(19) United States
(12) Patent Application Publication
(10) Pub. No.: US 2023/0150277 A1
(43) Pub. Date: May 18, 2023

(54) INKJET PRINTING APPARATUS AND PRINTING METHOD OF BIPOLAR ELEMENT USING THE SAME

(71) Applicant: Samsung Display Co., LTD., Yongin-si, Gyeonggi-do (KR)

(72) Inventors: Byung Chul LEE, Hwaseong-si, Gyeonggi-do (KR); Heung Cheol JEONG, Hwaseong-si, Gyeonggi-do (KR); Myung Soo HUH, Suwon-si, Gyeonggi-do (KR); Jin Oh KWAG, Yongin-si, Gyeonggi-do (KR)

(73) Assignee: Samsung Display Co., LTD., Yongin-si, Gyeonggi-do (KR)

(21) Appl. No.: 17/920,538

(22) PCT Filed: Apr. 1, 2021
(86) PCT No.: PCT/KR2021/004073

§ 371 Date: Oct. 21, 2022

(30) Foreign Application Priority Data
Apr. 22, 2020 (KR) 10-2020-0048774

(51) Int. Cl. B41J 11/00

(52) U.S. Cl. CPC B41J 11/00216

(57) ABSTRACT

Provided are an inkjet printing apparatus and a printing method of a bipolar element by using the inkjet printing apparatus. The inkjet printing apparatus includes: a stage that moves in a first direction; an inkjet device that sprays ink on the stage; a. plurality of electric field generating devices that generate an electric field on the stage, are spaced apart from the stage, and are movable in the first direction independently from the stage; a light irradiation device that irradiates the stage with light; and a drying device that dries the ink sprayed on the stage, wherein the inkjet device, the light irradiation device, and the drying device are arranged along the first direction,

### CROSS-REFERENCE TO RELATED APPLICATION(S)

This application is a national entry of International Application No. PCT/KR2021/004073, filed on Apr. 1, 2021, which claims under 35 U.S.C. §§ 119(a) and 365(b) priority to and benefits of Korean Patent Application No. 10-2020-0048774, filed on Apr. 22, 2020, in the Korean Intellectual Property Office (KIPO), the entire contents of which are incorporated herein by reference.

### BACKGROUND

### 1. Technical Field

Embodiments relate to an inkjet printing apparatus and a printing method of a bipolar element by using the inkjet printing apparatus.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED). The examples of the light emitting diode include an organic light emitting diode (OLED) by using an organic material as a fluorescent material and an inorganic light emitting diode by using an inorganic material as a fluorescent material.

### SUMMARY

Embodiments provide an inkjet printing apparatus capable of continuously performing different processes by disposing a plurality of devices performing a printing process in a process line.

Embodiments also provide a printing method of bipolar elements capable of improving a degree of alignment of the bipolar elements.

It should be noted that aspects of the disclosure are not limited thereto and other aspects, which are not mentioned herein, will be apparent to those of ordinary skill in the art from the following description.

According to an embodiment, an inkjet printing apparatus may include a stage that moves in a first direction, an inkjet device that sprays ink onto the stage, a plurality of electric field generating devices that generate an electric field on the stage, are spaced apart from the stage, and are movable in the first direction independently from the stage, and, a light irradiation device that irradiates the stage with light, and a drying device that dries the ink jetted onto the stage, wherein the inkjet device, the light irradiation device, and the drying device may be disposed along the first direction.

The plurality of electric field generating devices may be configured to generate the electric field on the stage with moving along the stage.

The plurality of electric field generating devices may include a first electric field generating device disposed on a side of the stage and a second electric field generating device disposed on another side of the stage, and the first electric field generating device and the second electric field generating device may be spaced apart from each other and may be movable in the first direction independently from each other.

At least one of the first electric field generating device and the second electric field generating device may be configured to move in a direction opposite to a moving direction of the stage in case that the stage moves to the drying device.

The inkjet device may be configured to spray the ink onto the stage on which the electric field may be generated by the plurality of electric field generating devices.

The ink may include a solvent and a plurality of bipolar elements dispersed in the solvent, and end portions of the bipolar elements may be oriented to have initial orientation directions by the electric field.

The light irradiation device may be configured to irradiate the ink disposed in the electric field with the light.

In case that the ink is irradiated with the light, the initial orientation directions of end portions of some of the bipolar elements may be changed by the electric field and the light.

The inkjet printing apparatus may further comprise a plurality of rails including a first rail and a second rail extending in the first direction, and a plurality of frames including a first frame and a second frame disposed above the first rail and the second rail, wherein the stage may be disposed on the first rail, the plurality of electric field generating devices may be disposed on the second rail, and the stage and the plurality of electric field generating devices may be configured to pass below the plurality of frames with moving in the first direction.

The inkjet device may be disposed on the first frame, and the light irradiation device may include a first light irradiation device disposed on the first frame and a second light irradiation device disposed on the second frame spaced apart from the first frame in the first direction.

The ink may be sprayed in case that the stage moves to the first light irradiation device, and the first light irradiation device may be configured to irradiate the stage with the light while the ink is sprayed onto the stage.

The second light irradiation device may be configured to irradiate the stage with the light after the ink is sprayed onto the stage.

The drying device may include a first drying device to which the plurality of electric field generating devices and the stage move, and the stage may be configured to move to the first drying device in a state in which the electric field is generated.

The drying device may further include a second drying device including an electric field generating unit different from the plurality of electric field generating devices, and the electric field generating unit may be configured to generate an electric field on the stage in case that the stage moves to the second drying device.

The inkjet printing apparatus may further comprise a sub-stage which is disposed below the second drying device and on which the electric field generating unit is disposed, wherein the stage and the plurality of electric field generating devices may be configured not to move to the second drying device.

According to an embodiment, a printing method of a bipolar element, may include providing a target substrate, generating an electric field on the target substrate, and spraying ink onto the target substrate, the ink including a solvent and bipolar elements dispersed in the solvent, arranging the bipolar elements on the target substrate by irradiating the ink disposed in the electric field with light, and seating the bipolar elements on the target substrate by removing the solvent of the ink.

In the spraying of the ink onto the target substrate, end portions of the bipolar elements may be oriented to have initial orientation orientation directions by the electric field.

In the arranging of the bipolar elements, the initial directions of end portions of some of the bipolar elements may be changed by by the electric field and the light.

The target substrate may be irradiated with the light in case that the ink is sprayed.

The seating of the bipolar elements may include removing the solvent in a state in which the electric field is generated on the target substrate.

The target substrate may include a first electrode and a second electrode spaced apart from each other, and the end portions of the bipolar elements may be disposed on the first electrode and another end portion disposed on the second electrode.

In an inkjet printing apparatus according to an embodiment, devices for printing processes of bipolar elements may be disposed in a process line, and a stage may pass through the devices with moving in a direction. The printing processes of bipolar elements may be continuously performed according to the movement of the stage, such that a process time of the printing processes may be shortened or reduced.

For example, a stage and an electric field generating device may be spaced apart from each other and moved individually, such that the electric field generating device may prepare for the next printing process before a printing process is completed. Accordingly, an unnecessary preparation time between the printing processes repeated several times may be minimized, such that the overall process time may be further shortened or reduced.

The effects according to the embodiments are not limited by the contents described above, and more various effects are included in this disclosure.

### BRIEF DESCRIPTION OF THE DRAWINGS

FIG. 1 is a schematic view of an inkjet printing apparatus according to an embodiment;

FIG. 2 is a schematic perspective view illustrating an arrangement of an inkjet device, an electric field generating device, and a light irradiation device according to an embodiment;

FIG. 3 is a schematic perspective view illustrating an arrangement of a drying device and an inspection device according to an embodiment;

FIG. 4 is a schematic plan view illustrating the inkjet device, the electric field generating device, and the light irradiation device according to an embodiment;

FIG. 5 is a schematic cross-sectional view illustrating that ink is discharged from the inkjet device according to an embodiment;

FIG. 6 is a schematic cross-sectional view illustrating the ink discharged from the inkjet device according to an embodiment;

FIG. 7 is a schematic plan view illustrating a stage and the electric field generating device according to an embodiment;

FIGS. 8 and 9 are schematic views illustrating an operation of e electric field generating device according to an embodiment;

FIG. 10 is a schematic view illustrating that an electric field is generated on a target substrate by the electric field generating device according to an embodiment;

FIG. 11 is a schematic view illustrating that discharged bipolar elements are arranged on the target substrate according to an embodiment;

FIG. 12 is a schematic side view illustrating the inkjet device and the light irradiation device according to an embodiment;

FIG. 13 is a schematic cross-sectional view illustrating the light irradiation device according to an embodiment;

FIG. 14 is a schematic view illustrating hat bipolar elements arranged on the target substrate are irradiated with light according to an embodiment;

FIG. 15 is a schematic front view illustrating the drying device according to an embodiment;

FIG. 16 is a schematic view illustrating that the ink discharged onto the target substrate is dried and the bipolar elements are seated according to an embodiment;

FIG. 17 is a schematic view illustrating that a solvent of the ink is dried according to an embodiment,

FIG. 18 is a schematic view illustrating movement of the electric field generating device according to an embodiment;

FIG. 19 is a schematic front view illustrating the inspection device according to an embodiment;

FIG. 20 is a schematic plan view of an inkjet printing apparatus according to an embodiment;

FIG. 21 is a schematic front view illustrating a drying device according to an embodiment;

FIG. 22 is a schematic front view illustrating a drying device according to an embodiment;

FIG. 23 is a schematic view illustrating an electric field generating device according to an embodiment;

FIG. 24 is a flowchart illustrating a printing method of a bipolar element according to an embodiment;

FIGS. 25 to 28 are schematic cross-sectional views illustrating the printing method of a bipolar element according to an embodiment;

FIGS. 29 and 30 are schematic views illustrating inspecting bipolar elements printed on a target substrate according to an embodiment;

FIG. 31 is a schematic view of a light emitting element according to an embodiment;

FIG. 32 is a schematic plan view of a display device according to an embodiment;

FIG. 33 is a schematic plan view illustrating a pixel of the display device according to an embodiment; and

FIG. 34 is a schematic cross-sectional view taken along line IIIa-IIIa′, line IIIb-IIIb′, and line IIIc-IIIc′ of FIG. 33.

### DETAILED DESCRIPTION OF THE EMBODIMENTS

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that in case that a layer is referred to as being “on” another layer or substrate, it can be directly on another layer or substrate, or intervening layers may also be present. The same reference numbers indicate the same components throughout the specification. When an element, such as a layer, is referred to as being “connected to,” or “coupled to” another element or layer, it may be directly connected to, or coupled to the other element or layer or intervening elements or layers may be present. When, however, an element or layer is referred to as being “directly connected to,” or “directly coupled to” another element or layer, there are no intervening elements or layers present. To this end, the term “connected” may refer to physical, electrical, and/or fluid connection, with or without intervening elements.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Hereinafter, embodiments will be described with reference to the accompanying drawings.

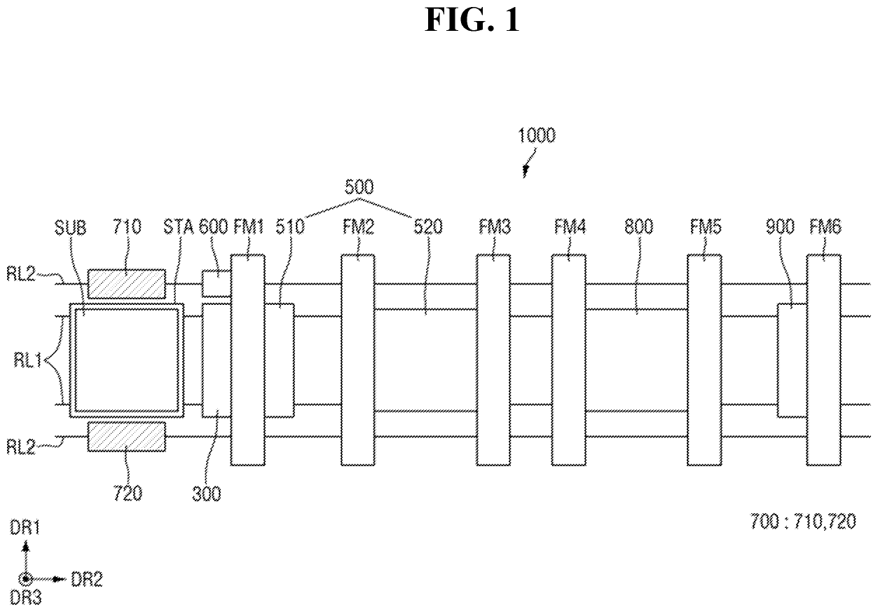

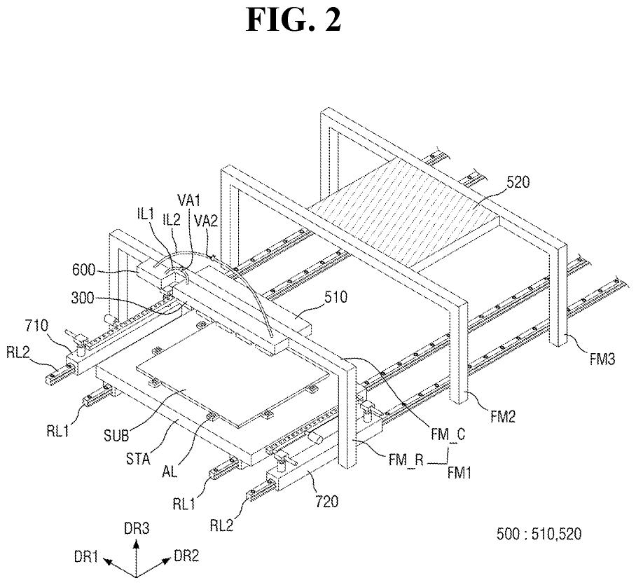

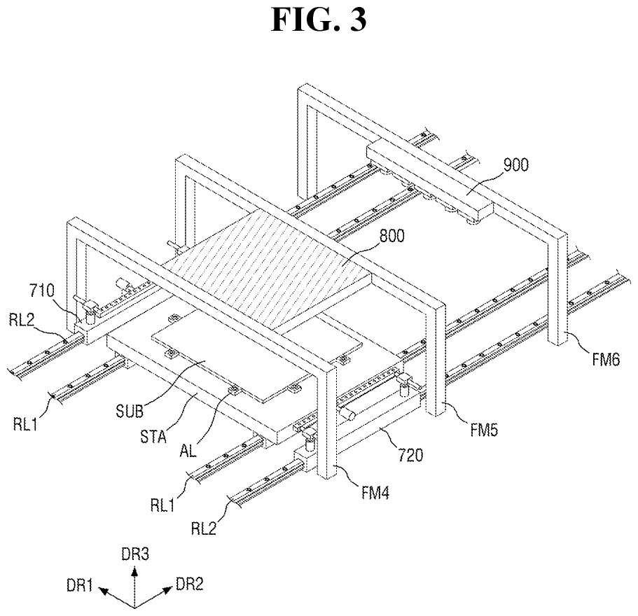

FIG. 1 is a schematic view of an inkjet printing apparatus 1000 according to an embodiment. FIG. 2 is a perspective view illustrating an arrangement of an inkjet device 300, an electric field generating device 700, and a light irradiation device 500 according to an embodiment. FIG. 3 is a schematic perspective view illustrating an arrangement of a drying device 800 and an inspection device 900 according to an embodiment.

FIG. 1 schematically illustrates an arrangement of respective components included in an inkjet printing apparatus 1000, FIG. 2 illustrates an inkjet device 300, a light irradiation device 500 (e.g., 510 and 520), and an electric field generating device 700 (e.g., 710 and 720) of the inkjet printing apparatus 1000, and FIG. 3 illustrates a drying device 800 and an inspection device 900 of the inkjet printing apparatus 1000. FIG. 1 illustrates the inkjet printing apparatus 1000 when viewed from above.

Referring to FIGS. 1 to 3, the inkjet printing apparatus 1000 according to an embodiment may include a stage STA, an inkjet device 300, light irradiation devices 500, electric field generating devices 700, and a drying device 800. For example, the inkjet printing apparatus 1000 may further include an inspection device 900.

In FIGS. 1 to 3, a first direction DR1, a second direction DR2, and a third direction DR3 are defined. The first direction DR1 and the second direction DR2 are directions disposed on the same plane and perpendicular to each other, and the third direction DR3 is a direction perpendicular to each of the first direction DR1 and the second direction DR2. The first direction DR1 refers to a transverse direction in the drawing, the second direction DR2 refers to a longitudinal direction in the drawing, and the third direction DR3 refers to an upward or downward direction in the drawing.

The inkjet printing apparatus 1000 may jet (or spray) ink onto the stage STA or a target substrate SUB disposed on the stage STA by using inkjet heads 330. In case that the ink is jetted onto the target substrate SUB, the electric field generating device 700 may generate an electric field on the target substrate SUB. Particles, for example, bipolar elements, included in the ink may be aligned in case that their orientation directions are changed by the electric field. The bipolar elements may be printed on the target substrate SUB in case that the stage STA moves via the light irradiation device 500 and the drying device 800. ‘Printing’ of the bipolar elements as used herein means discharging, spraying, or jetting the bipolar elements from the inkjet printing apparatus 1000 to an object. For example, printing the bipolar elements means seating the bipolar elements or the ink on the target substrate SUB, in addition to jetting the bipolar elements on the target substrate SUB by using the inkjet device 300. Hereinafter, components of the inkjet printing apparatus 1000 and a process of printing bipolar elements by using the inkjet printing apparatus 1000 will be described below.

In order to print the bipolar elements on the target substrate SUB, processes by using the inkjet device 300 that jets the ink including the bipolar elements, the electric field generating device 700 and the light irradiation device 500 that align the bipolar elements, and the drying device 800 that seats the bipolar elements on the target substrate SUB may be performed. In the inkjet printing apparatus 1000 according to an embodiment, processes of printing the bipolar elements may be continuously performed in case that the target substrate SUB moves via the inkjet device 300, the light irradiation device 500, and the drying device 800. For example, the electric field generating device 700 generating the electric field in order to align the bipolar elements may move along the target substrate SUB in a state which the electric field generating device 700 is disconnected (or spaced apart) from the stage STA on which the target substrate SUB is disposed. For example, the electric field generating device 700 generating the electric field may be movable in a direction (e.g., in the second direction DR2) independently from the stage STA on which the target substrate SUB. For example, the electric field generating device 700 generating the electric field may be separately movable from the stage STA or may be simultaneously movable with the stage STA. In the inkjet printing apparatus 1000, devices may be sequentially disposed in a direction (e.g., in the second direction DR2) so that different processes may be sequentially performed. For example, in the inkjet printing apparatus 1000, the inkjet device 300, the light irradiation device 500, and the drying device 800 may be disposed in a line along a direction (e.g., in the second direction DR2) in which the stage STA moves. For example, in the inkjet printing apparatus 1000, the electric field generating device 700 and the stage STA may be disconnected (or spaced apart) from each other, such that a time required for detachment between the electric field generating device 700 and the target substrate SUB may be saved, and a period between the preceding process and the subsequent process may be shortened, and continuity of the processes may thus be improved.

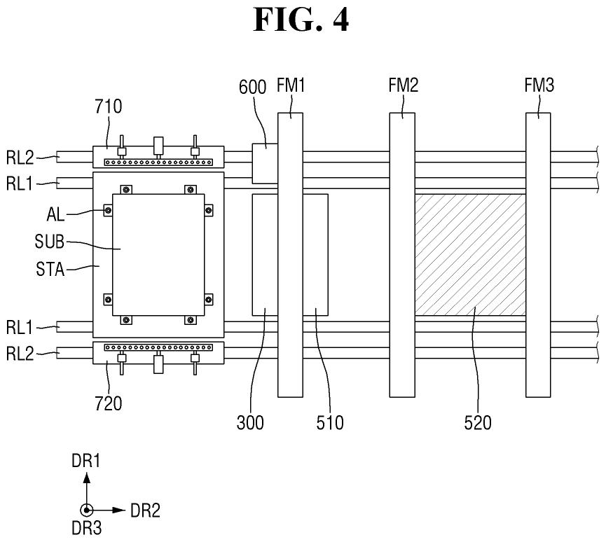

FIG. 4 is a schematic plan view illustrating the inkjet device 300, the electric field generating device 700, and the light irradiation device 500 according to an embodiment. FIG. 4 schematically illustrates an arrangement of the stage STA, the inkjet device 300, the light irradiation device 500, and the electric field generating device 700 of the inkjet printing apparatus 1000.

Referring to FIG. 4 in addition to FIGS. 1 to 3, the stage STA may provide a region in which the target substrate SUB is disposed. A shape of the stage STA is not limited, and as an example, the stage STA may have a rectangular shape with sides extending in the first direction DR1 and the second direction DR2. The stage STA may include long sides extending in the first direction DR1 and short sides extending in the second direction DR2. However, an overall shape of the stage STA in a plan view may change according to a shape of the target substrate SUB in a plan view. For example, in case that the target substrate SUB has a rectangular shape in a plan view, the stage STG may have a rectangular shape, and in case that the target substrate SUB has a circular shape in a plan view, the stage STA may also have a circular shape in a plan view. However, embodiments are not limited thereto, and the stage STA and the target substrate SUB may also have different shapes.

The inkjet printing apparatus 1000 may include first rails RL1 and second rails RL2 extending in the second direction DR2, and the stage STA may be disposed on the first rails RL1. The first rails RL1 and the second rails may extend in the second direction DR2, respectively, and the first rails RL1 may be disposed in a space between the second rails RL2 spaced apart from each other. The stage STA may move in the second direction DR2 on the first rails RL1 through a moving member. In case that the target substrate SUB is disposed on the stage STA, the stage STA may reciprocate in the second direction DR2 along the first rails RL1, and the particles may be printed on the target substrate SUB. An electric field generating device 700 to be described below may be disposed on the second rails RL2. The stage STA and the electric field generating device 700 may move in the second direction DR2 on the first rails RL1 or the second rails RL2.

Aligners AL may be disposed on the stage STA. The aligners AL may be disposed on each side of the stage STA, and a region surrounded by the aligners AL may be a region in which the target substrate SUB is disposed. For example, two aligners AL may be disposed to be spaced apart from each other on each side of the stage STA, and a total of eight aligners AL may be disposed on the stage STA. However, embodiments are not limited thereto, and the number, dispositions, and the like, of aligners AL may change according to a shape or a type of the target substrate SUB. For example, in some cases, the aligners AL may be omitted.

The target substrate SUB may be prepared on the stage STA. The target substrate SUB may provide a target space in which the particles printed by the inkjet printing apparatus 1000 are seated. As described below, specific members may be disposed on the target substrate SUB, and the particles may be seated or printed on the specific members. The target substrate SUB may be positioned on the stage STA in consideration of positions where the particles are printed together with the aligners AL.

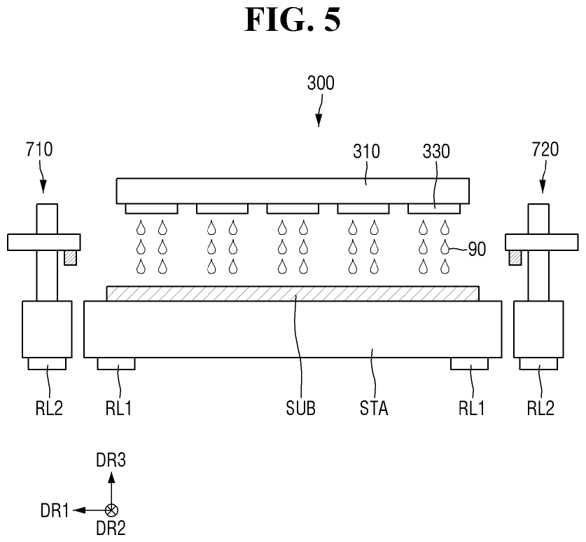

The inkjet device 300 may include inkjet heads 330 (see FIG. 5) and may be disposed on a first frame FM1. The inkjet device 300 may jet inks 90 (see FIG. 5) onto the target substrate SUB by using the inkjet heads 330 connected to an ink circulation unit 600.

The inkjet printing apparatus 1000 may include frames FM1 to FM6. The frames FM1 to FM6 may be disposed above the first rails RL1 and the second rails RL2, and devices performing a printing process of the bipolar elements 95 may be disposed on the frames FM1 to FM6. In an embodiment, the stage STA and the electric field generating device 700 may pass below the frames FM1 to FM6 with moving in the second direction DR2 on the rails RL1 and RL2.

The first frame FM1 may include support parts FM_C and FM_ R. The support parts FM_C and FM_R may include a first support part FM_C extending in the first direction DR1, which is a horizontal direction, and second support parts FM_R connected to the first support part FM_C and extending in the third direction DR3, which is a vertical direction. An extension direction of the first support part FM_C may be substantially the same as the first direction DR1, which is a long side direction of the stage STA. The inkjet device 300 may be mounted on the first support part FM_C.

The inkjet device 300 may be spaced apart from the stage STA passing below the first frame FM1 by a distance. The distance by which the inkjet device 300 is spaced apart from the stage STA may be adjusted by a height of the second support part FM_R of the first frame FM1. A distance between the inkjet device 300 and the stage STA spaced apart from each other may be adjusted within a range in which the inkjet device 300 has a certain distance from the target substrate SUB in case that the target substrate SUB is disposed on the stage STA, such that a space for a printing process may be secured.

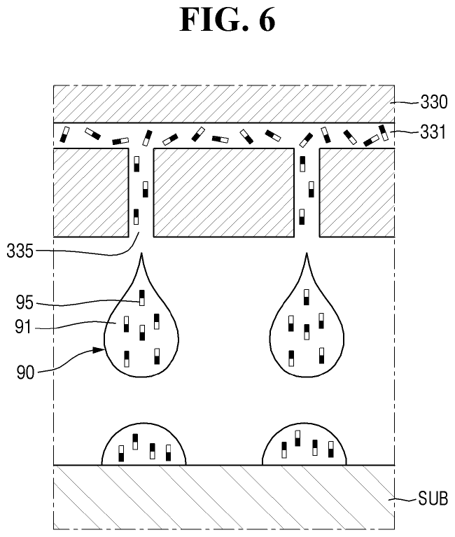

FIG. 5 is a schematic cross-sectional view illustrating that ink is discharged from the inkjet device 300 according to an embodiment. FIG. 6 is a schematic cross-sectional view illustrating the ink discharged from the inkjet device according to an embodiment.

Referring to FIGS. 5 and 6, the inkjet device 300 may include a first base part 310 and inkjet heads 330 disposed on a bottom surface of the first base part 310. The inkjet head 330 may include nozzles 335, and ink provided from the ink circulation unit 600 may be discharged (or sprayed) through the nozzles 335 of the inkjet head 330.

The inkjet heads 330 may be spaced apart from each other in a direction, and may be arranged in one row or a plurality of rows. For example, the inkjet heads 330 may be arranged in one row, but embodiments are not limited thereto. The inkjet heads 330 may be arranged in a greater number of rows, and may be misaligned with each other or be disposed to neighbor to each other. A shape of the inkjet head 330 is not limited, but as an example, the inkjet head 330 may have a rectangular shape.

In some embodiments, at least one inkjet head 330, for example, two inkjet heads 330 may form a pack (or a single pack) to be disposed adjacent to each other. However, the number of inkjet heads 330 included in the pack is not limited thereto, and for example, the number of inkjet heads 330 included in the pack may be about 1 to about 5. For example, only five inkjet heads 330 may be disposed in the inkjet device 300, but this is for schematically illustrating the inkjet device 300 and the number of inkjet heads 330 is not limited thereto.

In some embodiments, a width of the target substrate SUB measured in the first direction DR1 may be greater than a width of the inkjet device 300. For example, the inkjet device 300 may move in the first direction DR1 and jet (e.g., entirely jet) the ink 90 onto the target substrate SUB. For example, in case that target substrates SUB are provided on the stage STA, the inkjet device 300 may jet (or spray) the ink 90 onto each of the target substrates SUB with moving in the first direction DR1.

However, embodiments are not limited thereto, and the inkjet device 300 may be positioned outside the first rails RL1 and the second rails RL2, and may then move in the first direction DR1 and may jet the ink 90 onto the target substrate SUB. In case that the stage STA moves in the second direction DR2 to be positioned below the first frame FM1, the inkjet device 300 may move between the first rails RL1 and may jet the ink 90 through the inkjet head 330. An operation of such an inkjet head 330 is not limited thereto, and may be variously modified as long as the inkjet head 330 performs a similar process.

The inkjet head 330 disposed in the inkjet device 300 may jet the ink 90 onto the target substrate SUB disposed on the stage STA.

In an embodiment, the ink 90 may include a solvent 91 and bipolar elements 95 included in the solvent 91. In an embodiment, the ink 90 may be provided in a solution or colloidal state. For example, the solvent 91 may be acetone, water, alcohol, toluene, propylene glycol (PG) or propylene glycol methyl acetate (PGMA), triethylene glycol monobutyl ether (TGBE), diethylene glycol monophenyl ether (DGPE), an amide-based solvent, a dicarbonyl-based solvent, diethylene glycol dibenzoate, a tricarbonyl-based solvent, triethly citrate, a phthalate-based solvent, benzyl butyl phthalate, bis(2-ethlyhexyl) phthalate, bis(2-ethylhexyl) isophthalate, ethyl phthalyl ethyl glycolate, or the like, but embodiments are not limited thereto. The bipolar elements 95 may be included in a state in which the bipolar elements 95 are dispersed in the solvent 91, and be supplied to and discharged from the inkjet device 300.

The inkjet printing apparatus 1000 may further include the ink circulation unit 600. The ink circulation unit 600 may supply the ink 90 to the inkjet device 300, and the inkjet head 330 may discharge (or spray) the supplied ink 90. The ink 90 may be circulated between the ink circulation unit 600 and the inkjet head 330, and some of the ink 90 supplied to the inkjet head 330 may be discharged from the inkjet head 330, and the remainder of the ink 90 may be supplied to the ink circulation unit 600 again. In some embodiments, the ink circulation unit 600 may include ink storage parts, a pressure pump, a compressor, and a flow meter. In the ink circulation unit 600, the ink storage part may be connected to the inkjet head 330, and the ink storage part and the inkjet head may form an ink circulation system. A detailed description thereof will be omitted for descriptive convenience.

The ink circulation unit 600 may be connected to the inkjet head 330 through a first connection tube IL1 and a second connection tube IL2. For example, the ink circulation unit 600 may supply the ink 90 to the inkjet head 330 through the first connection tube IL1 and a flow rate of the supplied ink 90 may be adjusted through a first valve VA1. For example, the ink circulation unit 600 may be supplied with the remainder of the ink 90 remaining after being discharged from the inkjet head 330, through the second connection tube IL2. A flow rate of the ink 90 supplied to the ink circulation unit 600 through the second connection tube IL2 may be adjusted through a second valve VA2. As the ink 90 is circulated through the ink circulation unit 600, a deviation in the number of bipolar elements 95 included in the ink 90 discharged from the inkjet head 330 may be minimized.

The ink circulation unit 600 may be mounted on the first frame FM1, but embodiments are not limited thereto. The ink circulation unit 600 may be formed in the inkjet printing apparatus 1000, but a position or a shape of the ink circulation unit 600 is not limited. For example, the ink circulation unit 600 may be disposed through a separate device, and may be variously disposed as long as the ink circulation unit 600 is connected to the inkjet head 330.

The inkjet head 330 may include an inner tube 331 and nozzles 335 and may discharge the ink 90 through the nozzles 335. The ink 90 discharged from the nozzles 335 may be jetted onto the target substrate SUB provided on the stage STA. The nozzles 335 may be disposed on a bottom surface of the inkjet head 330 and may be arranged along a direction in which the inkjet head 330 extends.

The inner tube 331 may be connected to an inner flow path of the first base part 310, and may be supplied with the ink 90 from the ink circulation unit 600. The inner tube 331 may be supplied with the ink 90 through the first connection tube IL1 connected to the ink circulation unit 600, and the ink 90 remaining after being discharged from the nozzles 335 may be supplied to the ink circulation unit 600 through the second connection tube IL2. The inner tube 331 may be formed along an extension direction of the inkjet head 330. The ink 90 supplied through the inkjet device 300 may flow through the inner tube 331 and may be then discharged through the nozzles 335 of the inkjet head 330.

The nozzles 335 may be positioned on a lower surface of the inkjet head 330. The nozzles 335 may be spaced apart from each other and arranged along the extension direction of the inkjet head 330, and may be connected to the inner tube 331 to discharge the ink 90. For example, the nozzles 335 may be arranged in one row or a plurality of rows. In some embodiments, the number of nozzles 335 included in the inkjet head 330 may be about 128 to about 1800. An amount of the ink 90 jetted through the nozzles 335 may be adjusted according to a voltage applied to each nozzle 335. In an embodiment, an amount of the ink 90 discharged once from each nozzle 335 may be 1 to 50 pl (pico-litter), but embodiments are not limited thereto.

The ink 90 discharged through the nozzle 335 may include the solvent 91 and the bipolar elements 95 dispersed in the solvent 91. According to an embodiment, the bipolar element 95 may have a shape in which the bipolar element 95 extends in a direction. The bipolar elements 95 may be randomly dispersed in the ink 90, flow along the inner tube 331, and then be supplied to the nozzle 335. As the bipolar element 95 has a shape in which the bipolar element 95 extends in a direction, the bipolar element 95 may have an orientation direction, which is a direction toward which a major axis is directed. For example, the bipolar element 95 may include a first end portion having a first polarity and a second end portion having a second polarity, and the first end portion and the second end portion may be end portions (e.g., opposite end portions) of the bipolar element 95 in a major axis direction. The orientation direction of the bipolar element 95 extending in a direction may be defined on the basis of a direction toward which the first end portion is directed. The bipolar elements 95 flowing in the inner tube 331 and the nozzle 335 of the inkjet head 330 may be dispersed in random orientation directions rather than a constant orientation direction. However, embodiments are not limited thereto, and the bipolar elements 95 may flow in the inner tube 331 and the nozzle 335 in a state in which they have specific orientation directions.

The ink 90 discharged from the inkjet head 330 may be jetted onto the target substrate SUB. The bipolar elements 95 may be jetted onto the target substrate SUB with having specific orientation directions, and be then arranged on the target substrate SUB with having a constant orientation direction by the electric field generated by the electric field generating device 700. For example, the bipolar elements 95 may be aligned in a direction on the target substrate SUB by the electric field.

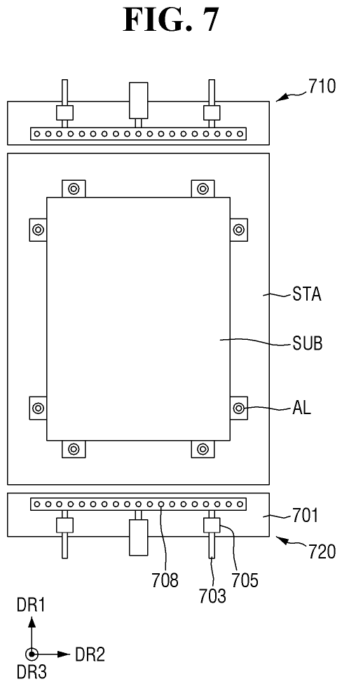

FIG. 7 is a schematic plan view illustrating a stage STA and the electric field generating device 700 according to an embodiment. FIG. 7 illustrates an arrangement of the stage STA, the target substrate SUB, and the electric field generating device 700.

Referring to FIG. 7 in addition to FIGS. 2 and 4, the inkjet printing apparatus 1000 may include electric field generating devices 700 disposed on the second rails RL2. The electric field generating device 700 may reciprocate (or move back and forth) in the second direction DR2 on the second rails RL2, similar to the stage STA. The electric field generating device 700 may be connected (e.g., electrically connected) to the target substrate SUB in order to generate the electric field on the target substrate SUB disposed on the stage STA. In case that the electric field generating device 700 and the target substrate SUB are connected (e.g., electrically connected) to each other, the electric field may be generated on the target substrate SUB by an electrical signal applied from the electric field generating device 700.

In an embodiment, the electric field generating device 700 may include a first electric field generating device 710 disposed on a side of the stage STA and a second electric field generating device 720 disposed on another side of the stage STA. The first electric field generating device 710 and the second electric field generating device 720 may be disposed on the second rails RL2, may be connected (e.g., electrically connected) to the target substrate SUB on a side and another side of the stage STA, respectively, and may generate an electric field of uniform strength regardless of a position even though an area of the target substrate SUB is great.

The first electric field generating device 710 and the second electric field generating device 720 may be driven individually or be driven simultaneously. For example, in case that the target substrate SUB is prepared on the stage STA and the ink 90 is jetted onto the target substrate SUB, the first electric field generating device 710 may form an electric field on the target substrate SUB, and the second electric field generating device 720 may not be connected to the target substrate SUB. Thereafter, the first electric field generating device 710 may be disconnected (e.g., electrically disconnected) from the target substrate SUB, and the second electric field generating device 720 may be connected to the target substrate SUB to form an electric field. For example, the electric field generating devices 700 may be simultaneously driven to form the electric fields, or may be sequentially driven to form the electric fields.

According to an embodiment, the electric field generating device 700 may move on the second rail RL2 in a state in which the electric field generating device 700 is disconnected from the stage STA. In case that the stage STA moves according to the printing process of the bipolar elements 95, the electric field generating device 700 may generate an electric field on the target substrate SUB in the printing process while (or with) moving together with the stage STA. For example, the electric field generating device 700 may be disconnected from the stage STA and moved before carrying the target substrate SUB on which the printing of the bipolar elements 95 is completed, and may be prepared in a state in which the electric field generating device 700 may be connected to another target substrate SUB.

For example, the first electric field generating device 710 and the second electric field generating device 720 may also be disconnected (or spaced apart) from each other and may be movable individually or independently from each other. In the printing process of the bipolar elements 95, the first electric field generating device 710 and the second electric field generating device 720 may move along the stage STA. However, for the subsequent printing process, any one of the first electric field generating device 710 and the second electric field generating device 720 may move in a direction opposite to a moving direction of the stage STA. A more detailed description thereof will be provided below.

The electric field generating device 700 (e.g., each of the first and second electric field generating devices 710 and 720) may include a probe support 701, a probe driver 703, a probe jig 705, and a probe pad 708. In the electric field generating device 700, the probe driver 703 and the probe jig 705 move, such that the probe pad 708 may be connected (e.g., electrically connected) to the target substrate SUB.

The probe support 701 may provide a space in which the probe driver 703, the probe jig 705, and the like, are disposed. The probe support 701 may be connected to the second rail RL2 and may move in the second direction DR2. The probe support 701 may be disposed on a side of the stage STA and have a shape in which the probe support 701 extends in a direction. For example, the probe support 701 may have a shape in which the probe support 701 extends in the second direction DR2 along the second rail RL2, and may have a length corresponding to short sides of the stage STA or the target substrate SUB extending in the second direction DR. However, embodiments are not limited thereto, and a shape of the probe support 701 may change according to a shape, a structure, or the like, of the electric field generating device 700, the target substrate SUB, or the stage STA.

The probe driver 703, the probe jig 705 connected to the probe driver 703 to receive an electrical signal, and the probe pad 708 connected to the probe jig 705 to transfer the electrical signal onto the target substrate SUB may be disposed on the probe support 701.

The probe driver 703 may be disposed on the probe support 701 and move the probe jig 705 and the probe pad 708. In an embodiment, the probe driver 703 may move the probe jig 705 in a horizontal direction and a vertical direction, for example, the first direction DR1 which is the horizontal direction and the third direction DR3 which is the vertical direction. The probe pad 708 may be connected to or disconnected from the target substrate SUB by driving of the probe driver 703. Among processes of the inkjet printing apparatus 1000, in a step of forming an electric field in the target substrate SUB, the probe driver 703 may be driven to connect the probe pad 708 to the target substrate SUB, and in other steps, the probe driver 703 may be driven again to disconnect the probe pad 708 from the target substrate SUB. This will be described in detail below with reference to other drawings.

The probe jig 705 may be connected to the probe pad 708 and may be connected to a separate voltage applying device. The probe jig 705 may transfer an electrical signal transferred from the voltage applying device to the probe pad 708 to form the electric field on the target substrate SUB. The electrical signal transferred to the probe jig 705 may be a voltage for forming the electric field, for example, an alternating current (AC) voltage.

The electric field generating device 700 may include probe jigs 705, and the number of probe jigs 751 is not limited. For example, two probe jigs 705 and two probe drivers 703 may be disposed in each of each of the first and second electric field generating devices 710 and 720, but the probe unit 750 may include a larger number of probe jigs 705 and a larger number of probe drivers 703 to form an electric field having a higher density on the target substrate SUB.

The probe pad 708 may generate an electric field on the target substrate SUB through the electrical signal transferred from the probe jig 705. The probe pad 708 may be connected to the target substrate SUB and may transfer the electrical signal to the target substrate SUB to generate the electric field on the target substrate SUB. As an example, the probe pad 708 may be in contact with an electrode, a power source pad, or the like, of the target substrate SUB, and the electrical signal of the probe jig 705 may be transferred to the electrode or the power source pad. The electrical signal transferred to the target substrate SUB may generate the electric field on the target substrate SUB. However, embodiments are not limited thereto, and the probe pad 708 may also be connected (e.g., electrically connected) to the target substrate SUB and may generate the electric field on the target substrate SUB, in a state in which the probe pad 708 is not in contact with the target substrate SUB.

A shape of the probe pad 708 is not limited, but in an embodiment, the probe pad 708 may have a shape in which the probe pad 708 extends in a direction so as to cover a side of the target substrate SUB, for example, a short side of the target substrate SUB extending in the second direction DR2.

In case that the target substrate SUB is prepared on the stage STA, the electric field generating device 700 may be connected (e.g., electrically connected) to the target substrate SUB by the movement of the probe driver 703. The electric field generating device 700 may generate the electric field on the target substrate SUB before, while, or after the ink 90 is jetted onto the target substrate SUB.

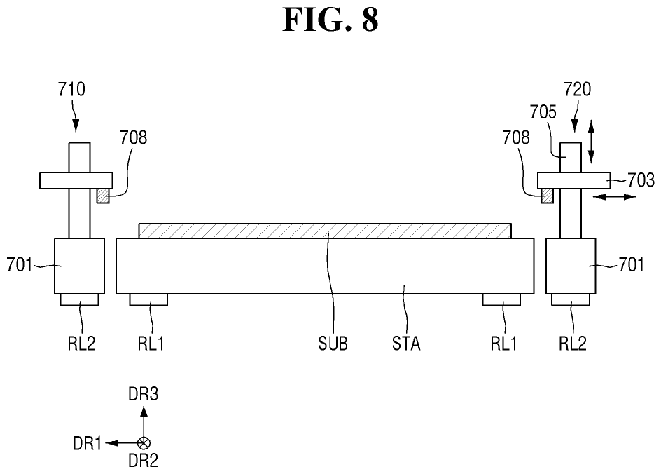

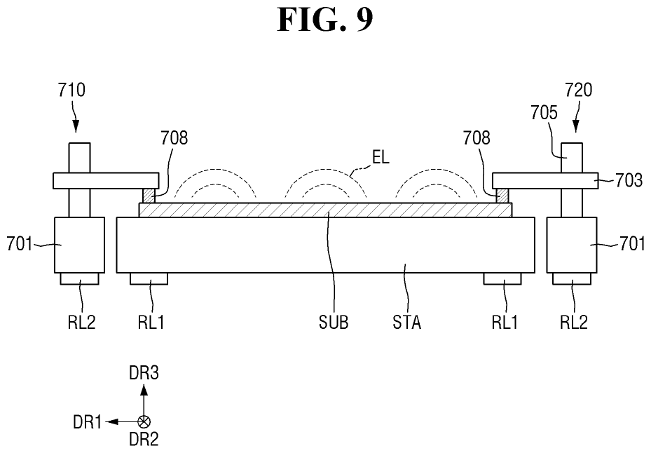

FIGS. 8 and 9 are schematic views illustrating an operation of the electric field generating device 700 according to an embodiment.

Referring to FIGS. 8 and 9, in a first state in which the electric field is not formed on the target substrate SUB, the probe pad 708 of the electric field generating device 700 may be in a state in which the probe pad 708 is spaced apart from the target substrate SUB. The probe driver 703 may be driven in the second direction DR2, which is the horizontal direction, and the third direction DR3, which is the vertical direction, such that the probe pad 708 may be spaced apart from the target substrate SUB.

In a second state in which the electric field is formed on the target substrate SUB, the probe driver 703 may be driven to connect (e.g., electrically connect) the probe pad 708 to the target substrate SUB. In an embodiment, the probe driver 703 may be driven in the third direction DR3, which is the vertical direction, and the first direction DR1, which is the horizontal direction, such that the probe pad 708 may be in contact with the target substrate SUB. Pad parts to which the electrical signal may be applied may be disposed on the target substrate SUB, and the probe pad 708 may be in contact with the pad part of the target substrate SUB to transfer the electrical signal. The probe jig 705 may transfer the electrical signal to the probe pad 708, and the electric field may be formed on the target substrate SUB.

For example, a configuration (or a structure) of the electric field generating device 700 is not limited thereto. In an embodiment, the electric field generating device 700 may be an antenna unit, a device including electrodes, or the like.

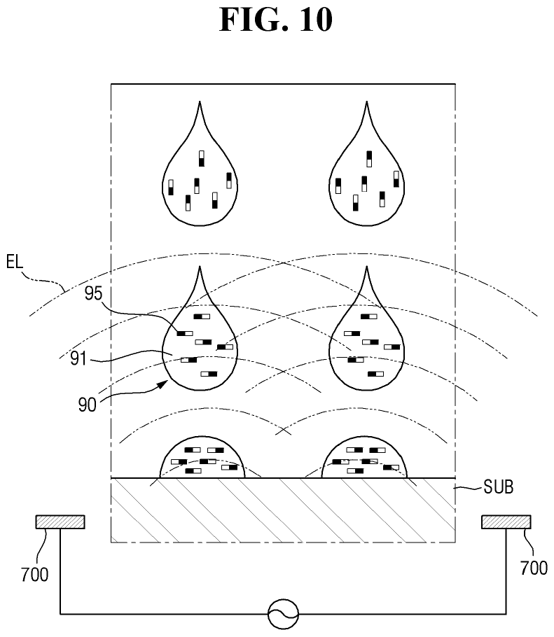

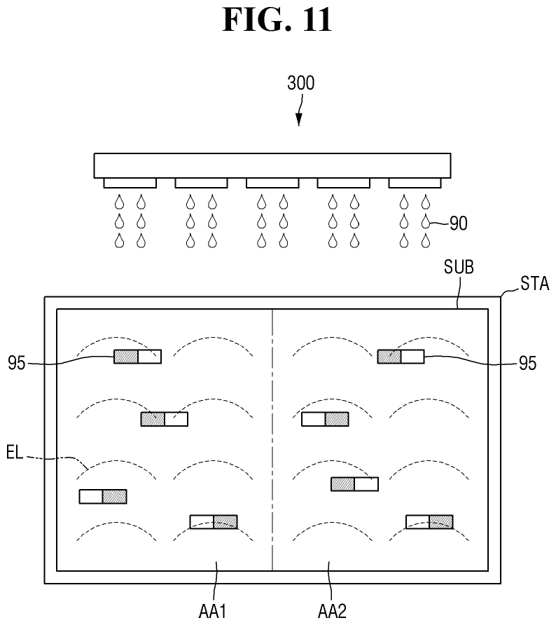

FIG. 10 is a schematic view illustrating that an electric field is generated on a target substrate SUB by the electric field generating device 700 according to an embodiment. FIG. 11 is a schematic view illustrating that discharged bipolar elements 95 are arranged on the target substrate SUB according to an embodiment.

Referring to FIGS. 10 and 11, the inkjet device 300 may jet (or spray) the ink 90 onto the target substrate in case that an electric field EL is generated on the stage STA or the target substrate SUB. As described above, the bipolar element 95 may include the first end portion and the second end portion that have the polarities, and in case that the bipolar element 95 is disposed in an electric field, a dielectrophoretic force may be transferred to the bipolar element 95, such that a position or an orientation direction of the bipolar element 95 may change. Positions and orientation directions of the bipolar elements 95 in the ink 90 jetted onto the target substrate SUB may change by the electric field EL generated by the electric field generating device 700. In the printing process of the bipolar elements 95 by using the inkjet printing apparatus 1000, in case that the ink 90 is jetted onto the target substrate SUB, a first alignment step of orienting the bipolar elements 95 in a direction may be performed.

In case that the inkjet device 300 discharges the ink 90 in a state in which the electric field generating device 700 generates the electric field EL on the target substrate SUB, the ink 90 discharged from the inkjet head 330 may pass through the electric field EL and be jetted onto the target substrate SUB. The bipolar elements 95 may receive a dielectrophoretic force by the electric field EL until the ink 90 reaches the target substrate SUB or even after the ink 90 reaches the target substrate SUB. The bipolar elements 95 may be dispersed in random orientation directions within the ink 90, and orientation directions and positions of the bipolar elements 95 may change by the electric field EL generated by the electric field generating device 700 after the bipolar elements 95 are discharged from the inkjet head 330.

In some embodiments, the electric field EL generated by the electric field generating device 700 may be formed in a direction parallel to an upper surface of the target substrate SUB. The bipolar elements 95 jetted onto the target substrate SUB may be oriented so that an extension direction of major axes of the bipolar elements 95 is the direction horizontal to the upper surface of the target substrate SUB by the electric field EL. For example, the bipolar elements 95 may be seated (or disposed) on the target substrate SUB in a state in which first end portions of the bipolar elements 95 having the polarity are oriented in a specific direction.

In case that the bipolar elements 95 are seated on the target substrate SUB, a degree of alignment may be measured in consideration of a deviation in orientation directions of the bipolar elements 95 or a deviation in positions of the bipolar elements 95 seated on the target substrate SUB. For the bipolar elements 95 seated on the target substrate SUB, a deviation in orientation directions and a deviation in seated positions of another bipolar elements 95 with respect to any one bipolar element 95 may be measured, and the degree of alignment of the bipolar elements 95 may be measured through these deviations. The ‘degree of alignment’ of the bipolar elements 95 may refer to deviations in orientation directions and seated positions of the bipolar elements 95 aligned on the target substrate SUB. For example, in case that the deviations in the orientation directions and the seated positions of the bipolar elements 95 are great, the degree of alignment of the bipolar elements 95 may be low. For example, in case that the deviations in the orientation directions and the seated positions of the bipolar elements 95 are small, the degree of alignment of the bipolar elements 95 may be high or improved.

A point in time at which the electric field generating device 700 generates the electric field EL on the target substrate SUB is not limited thereto. For example, the electric field generating device 700 may generate the electric field EL in case that the ink 90 is discharged from the nozzle 335 and reaches the target substrate SUB. Accordingly, the bipolar elements 95 may receive a dielectrophoretic force by the electric field EL until the bipolar elements 95 are discharged from the nozzle 335 and reach the target substrate SUB. Accordingly, a time for which the bipolar elements 95 are disposed in the electric field EL may increase, and may be jetted onto the target substrate SUB in case that their positions and directions change within the ink 90. However, embodiments are not limited thereto, and in some cases, the electric field generating device 700 may also generate the electric field EL after the ink 90 is seated on the target substrate SUB. For example, the electric field generating device 700 may generate the electric field EL when or after the ink 90 is jetted from the inkjet head 330.

For example, the bipolar element 95 jetted onto the target substrate SUB may be oriented in a direction by the electric field EL formed by the electric field generating device 700. However, in some embodiments, the bipolar elements 95 may include a semiconductor material having a high specific gravity, and the solvent 91 of the ink 90 may be a solution having a high viscosity so that the bipolar elements 95 having the high specific gravity may be dispersed in the solution for a long time. For example, positions and directions of the bipolar elements 95 may not be smoothly changed by the electric field EL generated by the electric field generating device 700. For example, the bipolar elements 95 may include first end portions and second end portions having different polarities, and any one of the first end portions and the second end portions of the bipolar elements 95 may be oriented in a direction toward which the electric field EL is directed (or oriented). Referring to FIG. 11, even though the bipolar elements 95 are oriented by the electric field EL to have the initial orientation directions, in case that a viscosity of the solvent 91 is high or alignment reactivity of the bipolar elements 95 by the electric field EL is low, directions of specific end portions of the bipolar elements 95 may not be constant.

The inkjet printing apparatus 1000 according to an embodiment may include a light irradiation device 500 irradiating the ink with light in order to improve a degree to which the bipolar elements 95 are oriented by the electric field EL. In case that the ink 90 is irradiated with the light when or before the electric field generating device 700 generates the electric field EL, dipole moments of the bipolar elements 95 may become great, and the bipolar elements 95 may receive a stronger force even with the electric field EL of the same strength. For example, the alignment reactivity of the bipolar elements 95 by the electric field EL may increase. Thus, the initial orientation directions of the bipolar elements 95 may be further changed by the electric field EL and the light. Accordingly, the final orientation directions of the bipolar elements 95 may be aligned more uniformly.

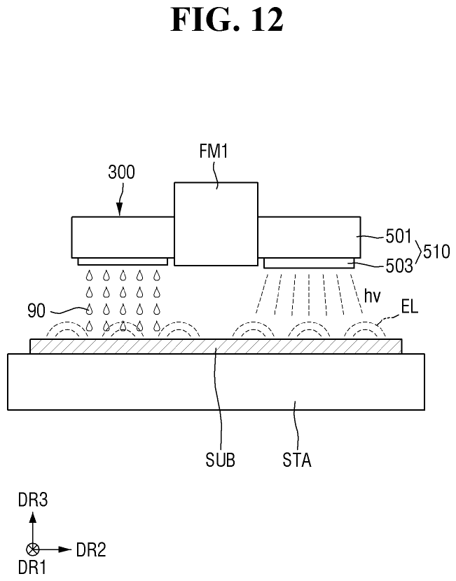

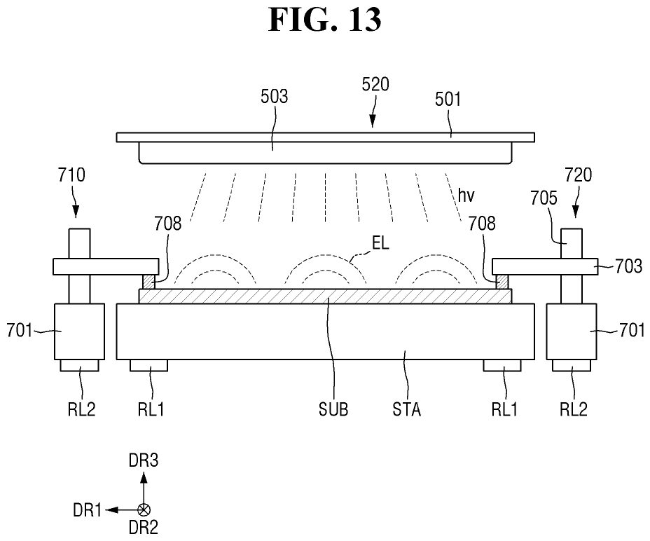

FIG. 12 is a schematic side view illustrating the inkjet device 300 and the light irradiation device 500 according to an embodiment. FIG. 13 is a schematic cross-sectional view illustrating the light irradiation device 500 according to an embodiment. FIG. 12 illustrates side surfaces of the inkjet device 300 and a first light irradiation device 510 disposed on the first frame FM1 together, and FIG. 13 is a schematic front view illustrating that a second light irradiation device 520 irradiates the target substrate SUB with light hv.

Referring to FIGS. 12 and 13, the inkjet printing apparatus 1000 may include at least one light irradiation device 500 (e.g., 510 and 520). According to an embodiment, the light irradiation device 500 may include a second light irradiation device 520 disposed between a second frame FM2 and a third frame FM3 in addition to a first light irradiation device 510 disposed on the first frame FM1 like the inkjet device 300.

The inkjet printing apparatus 1000 may include a larger number of frames FM2 to FM6 in addition to the first frame FM1 on which the inkjet device 300 is disposed. Frames FM2 to FM6 may be spaced apart from each other along a direction in which the first rails RL1 and the second rails RL2 extend. The inkjet printing apparatus 1000 may include the frames FM2 to FM6 so that devices for the printing process and an inspection process of the bipolar elements 95 may be disposed. Each of the frames FM2 to FM6 may include a first support part FM_C and a second support part FM_R, similar to the first frame FM1, and necessary devices may be disposed on the frames FM2 to FM6. A shape and an arrangement of each of the frames FM2 to FM6 may be substantially the same as those of the first frame FM1 as described above by way of example, and a detailed description thereof will thus be omitted for descriptive convenience.

Each light irradiation device 500 (e.g., 510 and 520) may include a second base part 501 and a light irradiation unit 503.

The second base part 501 may have a shape in which the second base part 501 extends in a direction, similar to the first base part 310 of the inkjet device 300. The second base part 501 may have a shape in which the second base part 501 extends in the first direction DR1 so as to correspond to the long sides of the stage STA or the target substrate SUB, for example, sides extending in the first direction DR1. A schematic shape of the second base part 501 of the light irradiation device 500 is illustrated in the drawings, but embodiments are not limited thereto. The second base part 501 of the light irradiation device 500 may also have a shape independent of shapes of the stage STA and the target substrate SUB. Embodiments are not limited thereto.

The light irradiation unit 503 may be disposed on the second base part 501. The light irradiation unit 503 may irradiate the target substrate SUB disposed on the stage STA with light hv. A manner in which the light irradiation unit 503 is disposed on the second base part 501 is not limited. For example, the light irradiation unit 503 may be fastened (e.g., directly fastened) to a lower surface of the second base part 501, but the light irradiation unit 503 may be coupled to or mounted on the second base part 501 through a separate member.

A type of the light irradiation unit 503 is not limited. In some embodiments, the light irradiation unit 503 may include mercury light, Fe-based metal halide-based, Ga-based metal halide-based, semiconductor light emitting elements, and the like. However, embodiments are not limited thereto.

In an embodiment, the first light irradiation device 510 may be mounted on the first frame FM1 together with the inkjet device 300, and may irradiate the target substrate SUB with the light hv simultaneously with a process of jetting the ink 90 in the printing process of the bipolar elements 95. Referring to FIG. 11, the ink 90 may be jetted onto the electric field EL generated by the electric field generating device 700, on the target substrate SUB disposed on the stage STA passing below the first frame FM1. In case that the stage STA passes through the inkjet device 300, a partial region of the target substrate SUB may be irradiated with the light hv emitted from the first light irradiation device 510 mounted on the first frame FM1. Since the first light irradiation device 510 irradiates only a region with the light hv in case that the stage STA moves, a primary light irradiation process performed by the first light irradiation device 510 may be performed in a scan manner according to the movement of the stage STA. Since the first light irradiation device 510 is mounted on the first frame FM1 together with the inkjet device 300, an area irradiated with the light hv from the first light irradiation device 510 may be small, and the target substrate SUB may not be sufficiently irradiated with the light hv. The inkjet printing apparatus 1000 according to an embodiment may further include the second light irradiation device 520 capable of irradiating an area greater than the area irradiated with the light from the first light irradiation device 510 with light, and in the printing process of the bipolar elements 95, a secondary light irradiation process following the primary light irradiation process may be performed.

The second base part 501 of the second light irradiation device 520 may be mounted on the second frame FM2 and the third frame FM3. The stage STA passing through the first frame FM1 may pass below the second light irradiation device 520 with passing through the second frame FM2 and the third frame FM3. The light irradiation unit 503 of the second light irradiation device 520 may have a greater area than the light irradiation unit 503 of the first light irradiation device 510 so as to cover the entirety of the target substrate SUB. The second light irradiation device 520 may also irradiate the target substrate SUB with the light hv in case that the stage STA passes through the second light irradiation device 520, but the second light irradiation device 520 may have a greater area than the first light irradiation device 510, and thus, a time for irradiating the target substrate SUB with the light hv by the second light irradiation device 520 may be longer than a time for irradiating the target substrate SUB with the light hv by the first light irradiation device 510. The second light irradiation device 520 may have a greater area than the target substrate SUB, such that the target substrate SUB may be irradiated (e.g., entirely irradiated) with the light in the secondary light irradiation process.

According to an embodiment, the second light irradiation device 520 may irradiate the target substrate with the light hv after the ink 90 is jetted from the inkjet device 300, unlike the first light irradiation device 510. The inkjet printing apparatus 1000 may include light irradiation devices 500 (e.g., 510 and 520), and thus perform the light irradiation process for improving a degree of alignment of the bipolar elements 95 twice.

For example, the second light irradiation device 520 may irradiate the target substrate with the light hv in case that the stage STA passes through the second light irradiation device 520, but embodiments are not limited thereto. In some embodiments, the stage STA may be subjected to the secondary light irradiation process in a state where the stage STA is stopped for a time below the second light irradiation device 520, and then move again. This may be adjusted according to a light irradiation degree for alignment of the bipolar elements 95.

The light irradiation device 500 may irradiate the ink 90 jetted (or sprayed) onto the target substrate SUB with the light hv to improve alignment reactivity of the bipolar elements 95 by the electric field EL. The bipolar elements 95 may include first end portions having a first polarity and second end portions having a second polarity different from the first polarity to have dipole moments. The bipolar elements 95 having the dipole moments may be oriented in a direction by receiving an electrical force by the electric field EL generated by the electric field generating device 700. In case that the light irradiation device 500 irradiates the bipolar elements 95 with the light hv, a partial polarity is further formed in the bipolar elements 95, such that the dipole moments may become greater, and the bipolar elements 95 may receive a greater electrical force by the electric field EL. Accordingly, the bipolar elements 95 dispersed in the ink 90 may have increased alignment reactivity, and may be oriented with a high degree of alignment on the target substrate SUB.

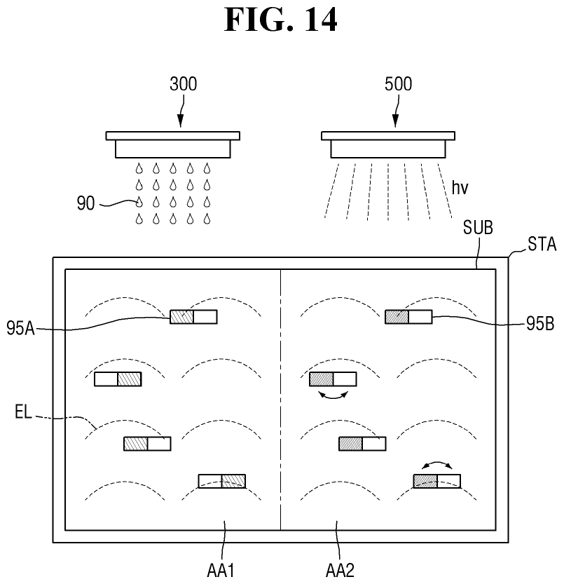

FIG. 14 is a schematic view illustrating that bipolar elements 95 arranged on the target substrate SUB are irradiated with light hv according to an embodiment.

Referring to FIG. 14, bipolar elements 95 may be jetted onto the target substrate SUB prepared on the electric field generating device 700, and the light irradiation device 500 may irradiate the ink 90 jetted onto the target substrate SUB with the light hv. In the printing process of the bipolar elements 95 by using the inkjet printing apparatus 1000, after the ink 90 is jetted onto the target substrate SUB, a second alignment step of orienting the bipolar elements 95 with irradiating the target substrate SUB with the light hv may be performed.

For example, as in the primary light irradiation process, a first region AA1 of the target substrate SUB may not be irradiated with the light hv, a second region AA2 of the target substrate SUB may be irradiated with the light hv, and there may be first bipolar elements 95A positioned in the first region AA1 and not irradiated with the light hv and second bipolar elements 95B positioned in the second region AA2 and irradiated with the light hv among the bipolar elements 95 jetted onto the target substrate SUB.

In the second bipolar elements 95B irradiated with the light hv, electrons of portions having polarities may react with or may be excited (or activated) by the irradiated light hv, such that the dipole moments between the first end portions having the first polarity and the second end portions having the second polarity may become greater. In case that the bipolar element 95 has a great bipolar moment, a magnitude of the dielectrophoretic force caused by the electric field EL generated on the target substrate SUB may be increased. As described above, orientation directions of the bipolar elements 95 may be determined on the basis of directions toward which the first end portions having the first polarity are directed (or oriented) in case that positions and directions of the bipolar elements 95 are changed by the electric field EL. The bipolar elements 95 having the greater dipole moments may have increased alignment reactivity with respect to the electric field EL, and the bipolar elements 95 may be aligned so that orientation directions thereof may be substantially uniform.

The first bipolar elements 95A jetted onto the first region AA1 may be oriented so that extension directions thereof are a specific direction by the electric field EL, but orientation directions toward which the first end portions of the first bipolar elements 95A are directed (or oriented) may not be uniform. The second bipolar elements 95B jetted onto the second region AA2 may be irradiated with the light hv, and may thus have increased alignment reactivity with respect to the electric field EL, and may be re-oriented with rotating or moving from an initial position (e.g., dotted line portion) so that the orientation directions toward which the first end portions of the second bipolar elements 95B are directed (or oriented) may be substantially uniform.

For example, the inkjet printing apparatus 1000 may include the electric field generating device 700 disconnected from the stage STA but capable of moving simultaneously with the stage STA. The ink 90 may be jetted onto the target substrate SUB or the target substrate SUB may be irradiated with the light hv according to the movement of the stage STA, and the electric field generating device 700 may continuously generate the electric field EL on the target substrate SUB regardless of a process step in the printing process of the bipolar elements 95. Accordingly, the electric field EL may be generated before or simultaneously with the jetting of the ink 90, such that a time for which the bipolar elements 95 may be disposed in the electric field EL may increase, and the generation of the electric field EL may be maintained even during the light irradiation process, such that the orientation directions of the bipolar elements 95 may be substantially uniform and a degree of alignment of the bipolar elements 95 may be improved.

In some embodiments, a central wavelength band of the light hv irradiated from the light irradiation device 500 is not limited. The light hv may change according to a type of the bipolar element 95 as described below, the bipolar element 95 may include a semiconductor material, and the central wavelength band of the light hv irradiated from the light irradiation device 500 may change according to a material of the bipolar element 95. In an embodiment, the central wavelength band of the light irradiated from the light irradiation device 500 may be in the range of about 300 nm to about 700 nm or in the range of about 350 nm to about 500 nm, but embodiments are not limited thereto.

In case that the bipolar elements 95 jetted onto the target substrate SUB are oriented or aligned in a direction, a drying process for removing the solvent 91 of the ink 90 may be performed. The inkjet printing apparatus 1000 according to an embodiment may further include the drying device 800 behind the light irradiation device 500.

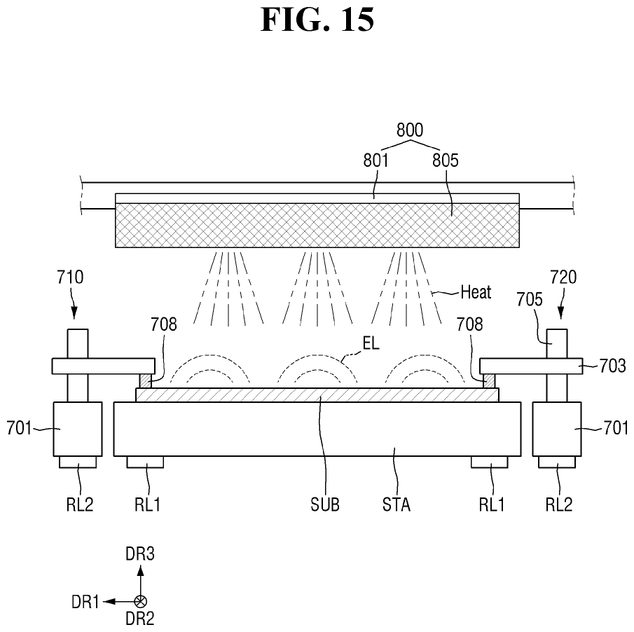

FIG. 15 is a schematic front view illustrating the drying device 800 according to an embodiment. FIG. 15 illustrates the drying device 800 irradiating the stage STA with heat when viewed from the front.

Referring to FIG. 15, the drying device 800 of the inkjet printing apparatus 1000 may include a third base part 801 and a heat treatment unit 805. According to an embodiment, the inkjet printing apparatus 1000 may include the drying device 800 disposed between a fourth frame FM4 and a fifth frame FM5.

As described above, the inkjet printing apparatus 1000 may include the frames FM1 to FM6. The frames FM1 to FM6 may be spaced apart from each other along a direction in which the first rails RL1 and the second rails RL2 extend. The fourth frame FM4 and the fifth frame FM5 may be further disposed behind the second frame FM2 and the third frame FM3 between which the second light irradiation device 520 is disposed, and the drying device 800 may be disposed between the fourth frame FM4 and the fifth frame FM5.

The third base part 801 may have a shape similar to that of the first base part 310 of the inkjet device 300 and the second base part 502 of the light irradiation device 500. A detailed description thereof will be omitted for descriptive convenience.

The heat treatment unit 805 may be disposed on the third base part 801. The heat treatment unit 805 may irradiate an upper portion of the target substrate SUB disposed on the stage STA with heat. A drying device 800 that dries the solvent 91 through the heat by including the heat treatment unit 805 is described as an example of the drying device 800 in the specification, but embodiments are not limited thereto. The drying device 800 may be a device for drying the solvent 91 of the ink 90, and may include various units. For example, the drying device 800 may include an infrared radiation (IR) irradiation unit irradiating the target substrate with infrared. However, embodiments are not limited thereto.

A manner in which the heat treatment unit 805 is disposed on the third base part 801 is not limited. For example, the heat treatment unit 805 may be fastened (e.g., directly fastened) to the third base part 801, but the heat treatment unit 805 may be coupled to or mounted on the third base part 801 through a separate member. The heat treatment units 805 of the drying device 800 may be spaced apart from other members disposed on the target substrate SUB enough not for the other members to be damaged by the irradiated heat. For example, in some embodiments, a shielding device may be further disposed on a lower surface of the heat treatment unit 805. The shielding device may block (e.g., partially block) the heat irradiated from the heat treatment unit 805 so that the target substrate SUB may not be damaged.

The drying device 800 may irradiate the target substrate SUB with the heat in case that the stage STA passes through the drying device 800 behind the second light irradiation device 520. However, embodiments are not limited thereto, and the stage STA may be subjected to a drying process in a state in which is stopped for a time below the drying device 800.

The ink 90 jetted onto the target substrate SUB may include the solvent 91 in which the bipolar elements 95 are dispersed, in addition to the bipolar elements 95 oriented in a direction. The drying device 800 may remove the solvent 91 of the ink 90, and the bipolar elements 95 may be seated on the target substrate SUB so that positions thereof may be fixed. According to an embodiment, in order to prevent orientation directions and positions of the bipolar elements 95 from changing in case that the solvent 91 is removed, the inkjet printing apparatus 1000 may perform the drying process of the solvent 91 in a state in which the electric field generating device 700 generates the electric field EL on the target substrate SUB.

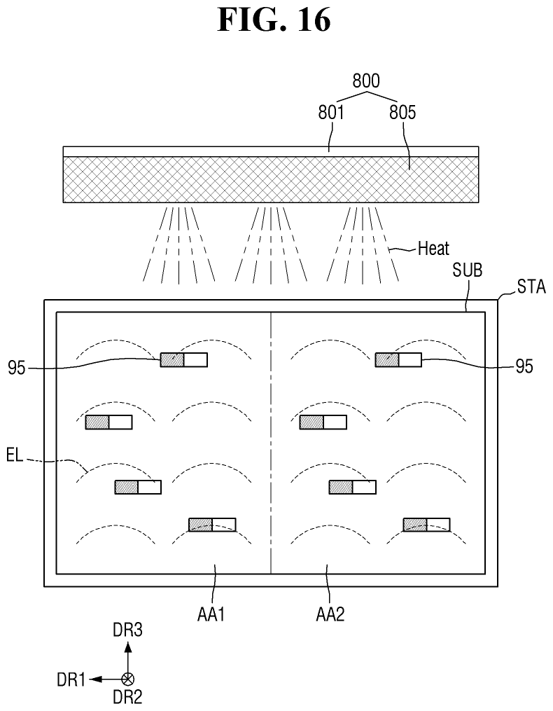

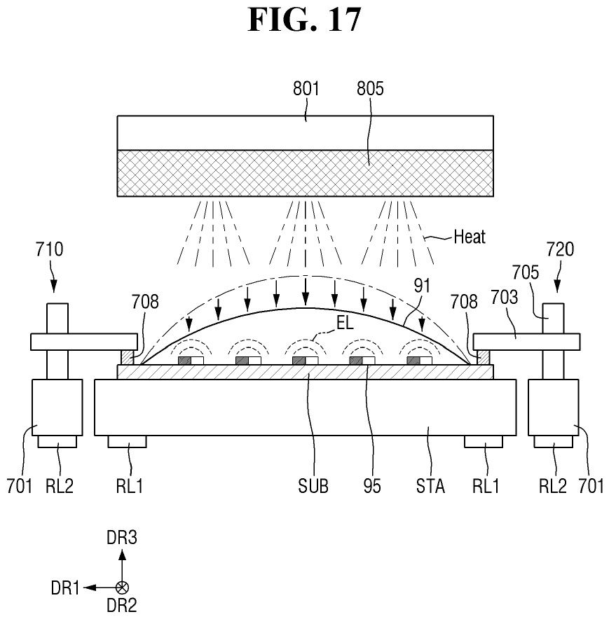

FIG. 16 is a schematic view illustrating that aligned bipolar elements 95 are seated on the target substrate SUB according to an embodiment FIG. 17 is a schematic view illustrating that a solvent of the ink is dried according to an embodiment.

Referring to FIGS. 16 and 17, bipolar elements 95 may be aligned in the first region AA1 and the second region AA2 of the target substrate SUB in a state in which the bipolar elements 95 are oriented in a direction. In case that the stage STA passes through the drying device 800, the target substrate SUB may be irradiated with the heat, and the bipolar elements 95 may be seated on the target substrate SUB in case that the solvent 91 is removed. However, as described above, the solvent 91 of the ink 90 may be a solvent having a high viscosity in order to maintain a state in which the bipolar elements 95 are dispersed for a long time. An initial alignment state of the bipolar elements 95 may change by an attractive force by a flow of a fluid or an attractive force between the solvent 91 and the bipolar elements 95 in a process in which the solvent 91 is dried or volatilized and removed by the heat. The electric field generating device 700 of the inkjet printing apparatus 1000 according to an embodiment may generate the electric field EL on the target substrate SUB even during the drying process of the solvent 91, and may prevent a misalignment problem that the orientation directions and positions of the bipolar elements 95 change.

For example, the drying device 800 of the inkjet printing apparatus 1000 may irradiate the upper portion of the target substrate SUB with the heat, and thus, the solvent 91 may be dried from a surface of the target substrate SUB, such that the occurrence of internal convection due to the heat may be minimized. In case that the convection occurs in the solvent 91 by heat treatment in an initial drying process after the secondary alignment step performed in the light irradiation process, the bipolar elements 95 may be misaligned. In the inkjet printing apparatus 1000 according to an embodiment, the drying device 800 may irradiate the upper portion of the stage STA or the target substrate SUB with the heat, and the solvent 91 may be dried from the surface of the target substrate SUB, such that a misalignment phenomenon of the bipolar elements 95 may be minimized.

In order to prevent the misalignment phenomenon of the bipolar elements 95, a strength of the electric field EL required in the drying process may be lower than that of the electric field EL required in an alignment process of the bipolar elements 95. The electric field generating device 700 may connect the target substrate SUB and the probe pad 708 to each other through the movement of the probe driver 703, and a time may be required in this process. In case that a lot of time is required in a process of connecting and disconnecting (e.g., electrically connecting and electrically disconnecting) the electric field generating device 700 and the target substrate SUB to and from each other, even though a process time is shortened by performing continuously the printing processes of the bipolar elements 95, it may take a lot of time to prepare for the next process.

In the inkjet printing apparatus 1000 according to an embodiment, the stage STA and the electric field generating device 700 may be disconnected from each other and moved, respectively, and before a printing process is completely completed, at least one electric field generating device 700 may be disconnected (e.g., electrically disconnected) from the target substrate SUB and moved.

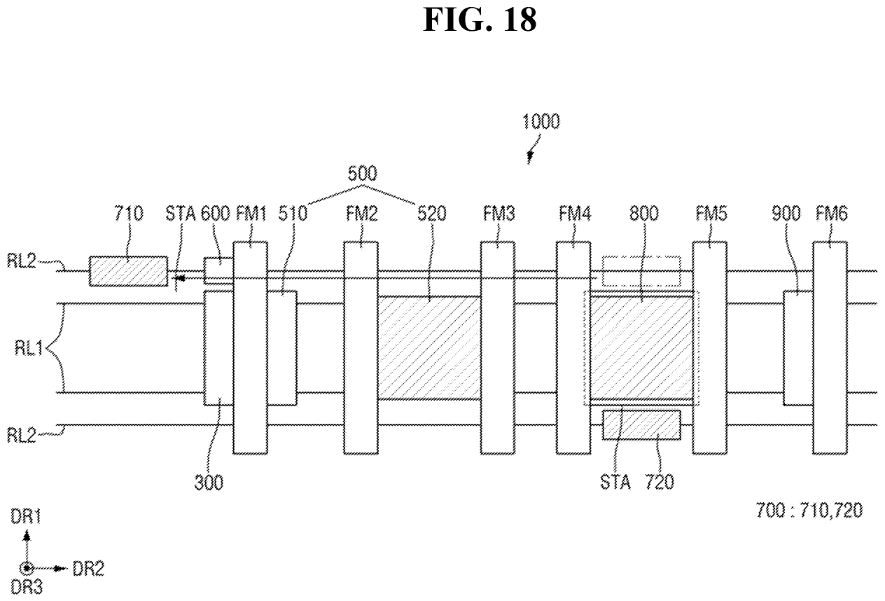

FIG. 18 is a schematic view illustrating movement of the electric field generating device 700 according to an embodiment.

Referring to FIG. 18, in case that the stage STA is subjected to the drying process in the drying device 800, the electric field generating device 700 may generate the electric field EL on the target substrate SUB. However, as described above, the strength of the electric field EL required in the drying process may be weaker than that of the electric field required in the alignment process, and thus, both the first electric field generating device 710 and the second electric field generating device 720 may not be connected to the target substrate SUB. In an embodiment, the first electric field generating device 710 and the second electric field generating device 720 may be disconnected (or spaced apart) from the stage STA and moved, and in case that the stage STA moves to a specific process device, at least one of the first electric field generating device 710 and the second electric field generating device 720 may move in a direction opposite to a moving direction of the stage STA. For example, in case that the stage STA moves to the drying device 800, the first electric field generating device 710 may be disconnected (e.g., electrically disconnecting) from the target substrate SUB and moved to a position before the first frame FM1, which is an initial position. The second electric field generating device 720 may be connected (e.g., electrically connected) to the target substrate SUB to generate the electric field EL during the drying process. The first electric field generating device 710 may move in the direction opposite to the moving direction of the stage STA to prepare for the next printing process, and the second electric field generating device 720 may move together with the stage STA to prevent the bipolar elements 95 from being misaligned in the drying process and be then disconnected (e.g., electrically disconnected) from the target substrate SUB.

For example, the first electric field generating device 710 may be disconnected from the stage STA in case that the stage STA moves to the drying device 800 to be subjected to the drying process, but embodiments are not limited thereto. In some embodiments, any one electric field generating device 700 may be disconnected from the stage STA in case that the stage STA moves to the second light irradiation device 520 and the secondary light irradiation process is performed. The electric field generating device 700 may be connected (e.g., electrically connected) to the target substrate SUB so as to generate the electric field EL in at least the secondary light irradiation process, and may be disconnected (e.g., electrically disconnected) from the target substrate SUB in the subsequent process and moved in order to prepare for the next process.

According to an embodiment, the electric field generating devices 700 (e.g., 710 and 720) or the electric field generating device 700 and the stage STA may move individually. Accordingly, a time for connecting and disconnecting (e.g., electrically connecting and electrically disconnecting) the electric field generating device 700 and the target substrate SUB to and from each other, which requires a lot of time in the printing process, may be shortened. In the inkjet printing apparatus 1000, devices for the printing process may be disposed in a line, such that the respective processes may be continuously performed, and thus, an unnecessary time between the processes may be minimized and a time required for preparing for the next process may be shortened.

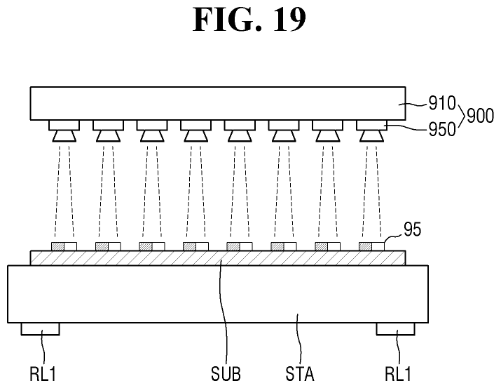

FIG. 19 is a schematic front view illustrating the inspection device 900 according to an embodiment.

Referring to FIG. 19, the inkjet printing apparatus 1000 may further include the inspection device 900 to inspect a degree of alignment of the bipolar elements 95 aligned on the target substrate SUB. In case that all of the solvents 91 are removed after the drying process, the electric field generating devices 700 may be disconnected (e.g., electrically disconnected) from the target substrate SUB and moved in order to prepare for the next process. For example, the stage STA may pass through the drying device 800 and moves to the inspection device 900, such that an inspection process of the degree of alignment of the bipolar elements 95 may be further performed.

The inspection device 900 of the inkjet printing apparatus 1000 may include a fourth base part 910 and sensing units 950. According to an embodiment, the inkjet printing apparatus 1000 may include the inspection device 900 disposed on a sixth frame FM6.

The fourth base part 910 may have a shape similar to that of the first base part 310 of the inkjet device 300 and the second base part 502 of the light irradiation device 500. A detailed description thereof will be omitted for descriptive convenience.

The sensing units 950 may be disposed on the fourth base part 910. The sensing unit 950 may measure the positions or the orientation directions of the bipolar elements 95 seated or aligned on the target substrate SUB, and may measure the degree of alignment of the bipolar elements 95 through deviations in the positions and the orientation directions of the bipolar elements 95.

For example, the sensing unit 950 may measure positions where the bipolar elements 95 are seated on the target substrate SUB, a distance between neighboring bipolar elements 95, the number of bipolar elements 95 seated in a region, or the like. In case that regions are defined on the target substrate SUB, the inkjet printing apparatus 1000 may print the number of the bipolar elements 95 on the regions defined on the target substrate SUB. The inspection device 900 may inspect whether or not the bipolar elements are seated in a state in which they are agglomerated with the other bipolar elements 95 in addition to how many bipolar elements 95 are accurately seated in the regions.

For example, since the bipolar elements 95 have a shape in which they extend in a direction and end portions (e.g., opposite end portions) of the bipolar elements 95 have different polarities, the orientation directions toward which the first end portions of the bipolar elements 95 having the first polarity are directed (or oriented) may be determined. The inspection device 900 may measure the degree of alignment of the bipolar elements 95 by measuring the orientation directions of the bipolar elements 95 with measuring the positions of the bipolar elements 95. The inspection device 900 may measure directions toward which the first end portions of the bipolar elements 95 are directed, angles between any line and the directions toward which the first end portions of the bipolar elements 95 are directed, e.g., orientation angles, and the like. In case that portions where the bipolar elements 95 are disposed on the target substrate SUB are specified, the inspection device 900 may inspect whether or not the bipolar elements 95 are accurately disposed on these portions. The inkjet printing apparatus 1000 may improve reliability of the printing process by confirming completeness of the printing process through seating position deviations, the degree of alignment, and the like, of the bipolar elements 95 measured by the inspection device 900, and at the same time, providing feedback to the respective devices based on information obtained through the confirmation of the completeness.

In case that the solvents 91 of the inks 90 are solvents having a high viscosity, the solvents 91 may not be completely removed in the drying process, and may remain as foreign materials on the target substrate SUB in a subsequent process. In order to completely remove the solvents 91 remaining on the target substrate SUB, the inkjet printing apparatus 1000 according to an embodiment may include a larger number of drying devices 800 to perform one or more drying processes in the printing process of the bipolar elements 95.

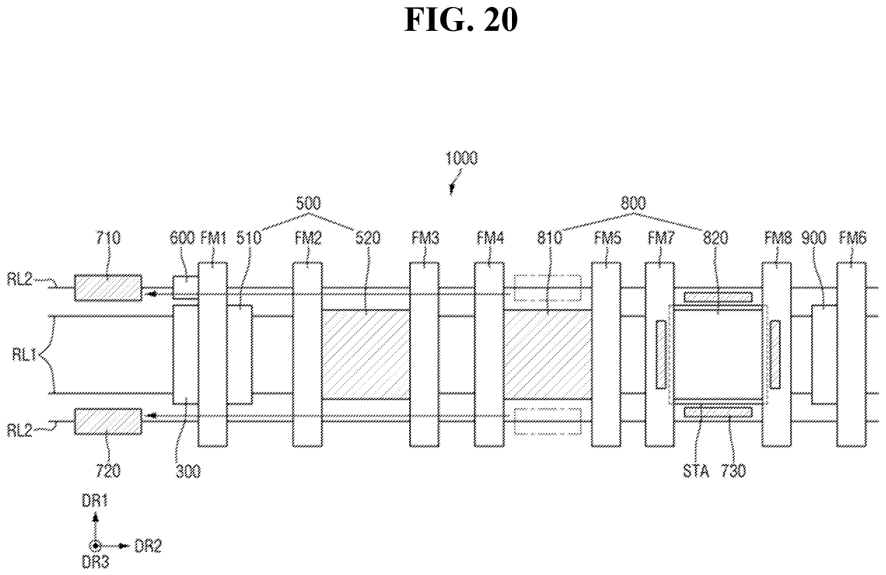

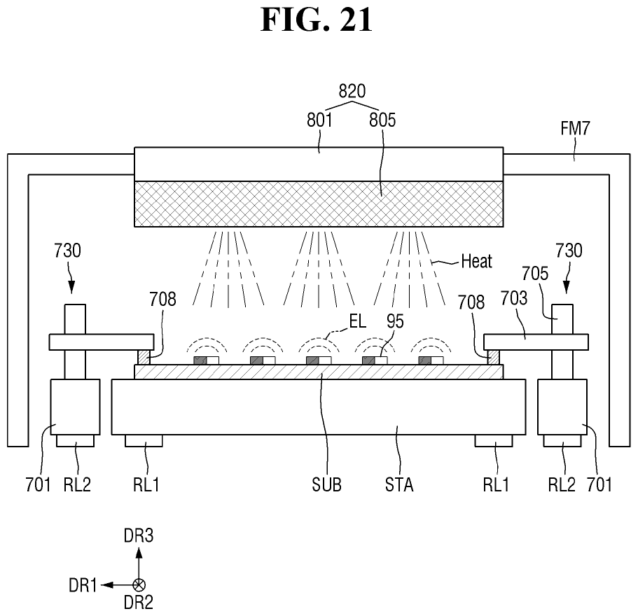

FIG. 20 is a schematic plan view of an inkjet printing apparatus 1000_1 according to an embodiment. FIG. 21 is a schematic front view illustrating a drying device 800 according to an embodiment.

Referring to FIGS. 20 and 21, an inkjet printing apparatus 1000_1 according to an embodiment may include a larger number of drying devices 800 (e.g., 810 and 820). The drying device 800 may include a first drying device 810 and a second drying device 820 disposed behind the second light irradiation device 520. The stage STA may be subjected to a primary drying process in the first drying device 810, and may then move to the second drying device 820 to be subjected to a secondary drying process. The inkjet printing apparatus 1000_1 according to an embodiment is different from the inkjet printing apparatus 1000 according to the above-described embodiment in that the inkjet printing apparatus 1000_1 further includes the second drying device 820 to perform drying processes in the printing process of the bipolar elements 95. A description of the first drying device 810 is substantially the same as that described above, and thus, the second drying device 820 will hereinafter be described in detail.

The inkjet printing apparatus 1000_1 may further include a seventh frame FM7 and an eighth frame FM8, and the second drying device 820 may be disposed between the seventh frame FM7 and the eighth frame FM8. The second drying device 820 may also include a third base part 801 and a heat treatment unit 805, and may irradiate the stage STA or the target substrate SUB moved below the second drying device 820 with heat.

Even though the primary drying process is performed in the first drying device 810, the solvents 91 disposed on the target substrate SUB may not be completely removed, and some of the solvents 91 may remain. As described above, the solvents 91 may be solvent materials having a high viscosity, and the solvents 91 may be removed from the surfaces of the target substrate SUB in the primary drying process in order to prevent the misalignment of the bipolar elements 95, and thus, some solvents 91 may remain on the target substrate SUB. The solvents 91 remaining on the target substrate SUB may remain as foreign materials in a subsequent process for manufacturing a product including the bipolar elements 95.

The inkjet printing apparatus 1000_1 may perform the drying process twice by including the drying devices 800 (e.g., 810 and 820) in order to completely remove the solvents 91 of the inks 90. After the primary drying process is performed through the first drying device 810, the bipolar elements 95 may be safely seated on the target substrate SUB, and a misalignment problem may not occur. Accordingly, in the secondary drying process by using the second drying device 820, a heat treatment process may be performed at a higher temperature than the primary drying process.

For example, in an embodiment, the inkjet printing apparatus 1000_1 may further include electric field generating units 730, which is different from the electric field generating device 700) and disposed in the second drying device 820. The electric field generating unit 730 may generate an electric field EL on the target substrate SUB by including a probe driver 703, a probe jig 705, and a probe pad 708, similar to the electric field generating device 700 (e.g., 710 and 720). However, the electric field generating units 730 may not move in the second direction DR2 along the stage STA unlike the first electric field generating device 710 and the second electric field generating device 720. The electric field generating units 730 may be disposed between the seventh frame FM7 and the eighth frame FM8, and may be connected (e.g., electrically connected) to the target substrate SUB to generate the electric field EL on the target substrate SUB in case that the stage STA moves to the second drying device 820. In case that the secondary drying process is performed at a high temperature in the second drying device 820, the electric field generating units 730 may prevent the bipolar elements 95 on the target substrate SUB from being misaligned.

Some electric field generating units 730 may be disposed on the second rails RL2 and be disposed on the sides (e.g., opposite sides) of the stage STA in the first direction DR1. Embodiments are not limited thereto, and in case that the stage STA moves to the second drying device 820, some electric field generating units 730 may move to the sides (e.g., opposite sides) of the stage STA in the second direction DR2 to be connected (e.g., electrically connect) to the target substrate SUB. For example, after some electric field generating units 730 may be mounted on the seventh frame FM7 and the eighth frame FM8, in case that the stage STA moves, the probe drivers 703 of some electric field generating units 730 move, such that some electric field generating units 730 may be connected to the target substrate SUB. For example, two electric field generating units 730 may be disposed on the sides of the stage STA in the first direction DR1 and two electric field generating units 730 may be disposed on the other sides of the stage STA in the second direction DR2, such that a total of four electric field generating units 730 may be disposed. However, embodiments are not limited thereto. In some cases, the two electric field generating units 730 disposed on the sides of the stage STA in the first direction DR1 may also be omitted, and the electric field generating devices 700 (e.g., 710 and 720) may also move to the second drying device 820 together with the stage STA.

Since the inkjet printing apparatus 1000_1 includes electric field generating units 730 disposed together with the second drying device 820, the electric field generating devices 700 (e.g., 710 and 720) may be disconnected from the stage STA after the first drying process performed in the first drying device 810. After the primary drying process, the bipolar elements 95 may remain on the stage STA in a state in which some of the solvents 91 are removed, and in case that the stage STA moves to the second drying device 820, misalignment of the bipolar elements 95 may be prevented by the electric field EL generated by the electric field generating units 730. Accordingly, the electric field generating devices 710 and 720 may not move to the second drying device 820, and may be disconnected from the stage STA to prepare for a subsequent printing process. In case that the inkjet printing apparatus 1000_1 includes stages STA, a target substrate SUB may be prepared on a second stage and the electric field generating devices 700 may move together with the second stage, in case that a first stage is subjected to the secondary drying process in the second drying device 820. Accordingly, even though a process time of the printing process is increased because the inkjet printing apparatus 1000_1 further includes the second drying device 820, a preparation time between printing processes may be shortened, such that an overall process time may be shortened.

For example, the stage STA may not move to the second drying device 820, and only the target substrate SUB may move to the second drying device 820. In some embodiments, the inkjet printing apparatus 1000_1 may further include a stage and electric field generating units 730 together with the second drying device 820. For example, only the target substrate SUB may move for the secondary drying process, and the stage STA and the electric field generating devices 700 may move to initial positions for a subsequent printing process.

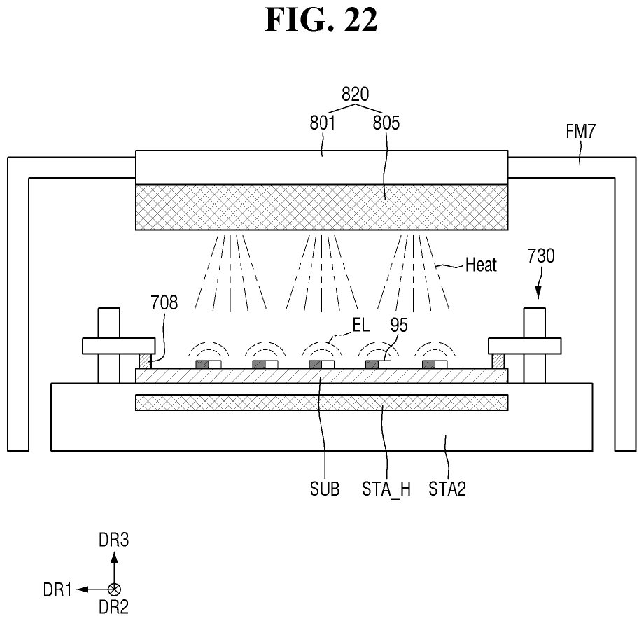

FIG. 22 is a schematic front view illustrating a drying device 800 according to an embodiment.

Referring to FIG. 22, an inkjet printing apparatus 1000_2 may further include a sub-stage STA2 disposed together with the second drying device 820. The electric field generating units 730 may be disposed on the sub-stage STA2, and in case that the target substrate SUB is prepared on the sub-stage STA2, the electric field generating units 730 may be connected to the target substrate SUB to generate an electric field EL. The inkjet printing apparatus 1000_2 according to an embodiment is different from the inkjet printing apparatus 1000 (or 1000_1) according to the above-described embodiment in that the inkjet printing apparatus 1000_2 further includes the sub-stage STA2 on which a secondary drying process is performed. Hereinafter, a redundant description will be omitted, and contents different from those described above will be described for descriptive convenience.

The sub-stage STA2 may be disposed below the second drying device 820 between the seventh frame FM7 and the eighth frame FM8. The sub-stage STA2 and the stage STA may have substantially the same shape. However, the sub-stage STA2 may not move in a direction, and may be fixedly disposed below the second drying device 820. However, embodiments are not limited thereto. For example, the sub-stage STA2 may not be disposed on the rails RL1 and RL2, but embodiments are not limited thereto, and the sub-stage STA2 may also be disposed on the first rails RL1 to move between the second drying device 820 and the inspection device 900.

In the secondary drying process, a drying process may be performed at a higher temperature than the primary drying process in order to completely remove the solvents 91. Since the secondary drying process is performed in a state in which the solvents 91 are removed to some extent unlike the primary drying process, the possibility of the occurrence of internal convection of the inks 90 is low. According to an embodiment, in order to completely remove the solvents 91 on the target substrate SUB, the sub-stage STA2 may include a heat sink STA_H capable of transferring heat below the target substrate SUB. The heat sink STA_H may be disposed inside the sub-stage STA2 and may irradiate a lower portion of the target substrate SUB disposed above the heat sink STA_H with heat. In the secondary drying process, the solvents 91 may be completely removed through the second drying device 820 disposed above the target substrate SUB and the heat sink STA_H transferring the heat below the target substrate SUB. For example, since the electric field generating units 730 disposed on the sub-stage STA2 generate the electric field EL on the target substrate SUB, misalignment of the bipolar elements 95 that may occur at the time of removal of the solvents 91 may also be prevented.

The target substrate SUB that is subjected to the primary drying process with passing through the first drying device 810 may move from the stage STA to the sub-stage STA2 through a separate transport device. In case that the target substrate SUB moves to the sub-stage STA2, the stage STA and the electric field generating device 700 may move to initial positions for a subsequent printing process. The inkjet printing apparatus 1000_2 according to an embodiment may further include the sub-stage STA2 on which the secondary drying process is performed, and thus, the stage STA may move in order to prepare for a subsequent process before the printing process ends, such that a total process time may be shortened.

In the electric field generating device 700, the probe pad 708 may be required to be accurate contact with the pad part disposed on the target substrate SUB in an aligned state in order for the probe pad 708 to be connected to the target substrate SUB in case that the probe driver 703 moves. In this process, it may take a lot of time to align the probe pad 708 and the target substrate SUB with and bring the probe pad 708 and the pad part into contact with each other, and a total process time of the printing process may increase. In an embodiment, the electric field generating device 700 may not be in direct contact with the target substrate SUB, and may be wirelessly connected to the target substrate SUB to generate the electric field EL on the target substrate SUB. Accordingly, since a contact process between the probe pad 708 of the electric field generating device 700 and the target substrate SUB is omitted, a preparation time of the printing process may be shortened.

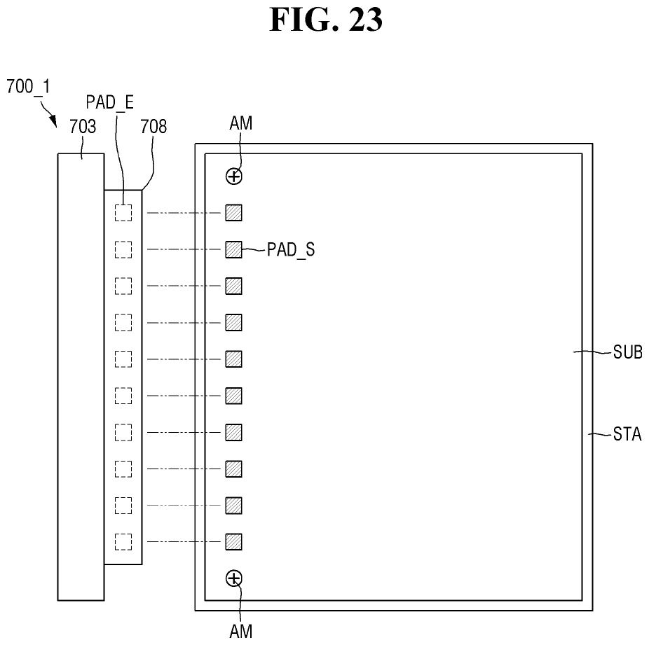

FIG. 23 is a schematic view illustrating an electric field generating device 700_1 according to an embodiment.

Referring to FIG. 23, in an electric field generating device 700_1 according to an embodiment, a probe pad 708 may include electrode pads PAD_E capable of forming electrical connections wirelessly. The electrode pads PAD_E may be connected (e.g., electrically connected) to pad parts PAD_S disposed on the target substrate SUB in a state in which they are not in direct contact with the pad parts PAD_S.

In case that the target substrate SUB is prepared on the stage STA, the electrode pads PAD_E of the probe pad 708 of the electric field generating device 700_1 may be aligned with the pad parts PAD_S of the target substrate SUB on the basis of alignment marks AM disposed on the target substrate SUB. In case that the electrode pads PAD_E and the pad parts PAD_S are wirelessly connected to each other by adjusting distances between the electrode pads PAD_E and the pad parts PAD_S, the electric field generating device 700_1 may generate an electric field EL on the target substrate SUB. For example, the target substrate SUB and the probe pads 708 of the electric field generating device 700_1 may be connected to each other in a state in which they are spaced apart from each other by a distance, but embodiments are not limited thereto. In some embodiments, the electrode pads PAD_E of the probe pad 708 of the electric field generating device 700_1 and the pad parts PAD_S of the target substrate SUB may be connected (e.g., electrically connected) to each other in a state in which they overlap each other in a thickness direction or the third direction DR3 and are aligned with each other. The electric field generating device 700_1 according to an embodiment may be different from the electric field generating device according to the above-described embodiment in that the electric field generating device 700_1 may wirelessly generate the electric field EL on the target substrate SUB. Other portions are substantially the same as those described above, and a detailed description thereof will thus be omitted for descriptive convenience.

Hereinafter, a printing method of a bipolar element 95 by using the inkjet printing apparatus 1000 according to an embodiment will be described in detail.

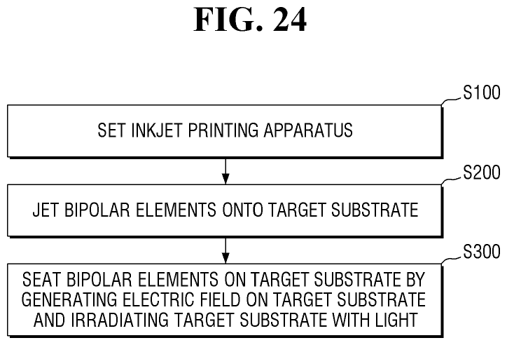

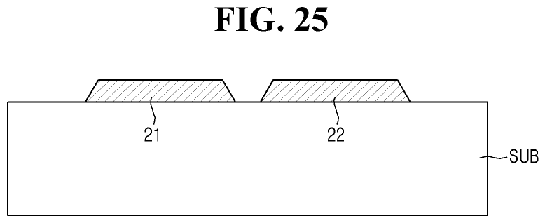

FIG. 24 is a flowchart illustrating a printing method of a bipolar element according to an embodiment. FIGS. 25 to 28 are schematic cross-sectional views illustrating the printing method of a bipolar element 95 according to an embodiment.

Referring to FIGS. 1 and 24 to 28, the printing method of a bipolar element 95 according to an embodiment may include setting the inkjet printing apparatus 1000 (S100), jetting the bipolar elements 95 onto the target substrate SUB (S200), and seating the bipolar elements 95 on the target substrate SUB by generating an electric field on the target substrate SUB and irradiating the target substrate SUB with light (S300).

The printing method of a bipolar element 95 according to an embodiment may be performed by using the inkjet printing apparatus 1000 described above with reference to FIG. 1, and in the seating of the bipolar elements 95 on the target substrate SUB, the electric field generating device 700 may generate the electric field EL on the target substrate SUB. The electric field EL may be generated when or after the ink 90 is jetted from the inkjet device 300 and may be continuously generated in the light irradiation process and the drying process.

For example, the inkjet printing apparatus 1000 may be set (S100). The setting (S100) of the inkjet printing apparatus 1000 may be tuning the inkjet printing apparatus 1000 according to a target process. For precise tuning, an inkjet print test process may be performed on an inspection substrate, and a set value of the inkjet printing apparatus 1000 may be adjusted according to a test result.

For example, the inspection substrate may be first prepared. The inspection substrate and the target substrate SUB may have the substantially same structure, but a bare substrate such as a glass substrate may be used as the inspection substrate.

For example, a water repellent treatment may be performed on an upper surface of the inspection substrate. The water repellent treatment may be performed by fluorine coating, a plasma surface treatment, or the like.

For example, the ink 90 including the bipolar elements 95 may be jetted (or sprayed) onto the upper surface of the inspection substrate by using the inkjet printing apparatus 1000, and droplets for each inkjet head 330 may be measured. The measurement of the droplets for each inkjet head 330 may be performed in a manner of confirming a size of a droplet at the moment of jetting the ink and a size of a droplet applied to the substrate by using a camera. In case that the measured droplets are different from reference droplets, a voltage for each corresponding inkjet head 330 may be adjusted so that the reference droplets may be discharged. Such an inspection method may be repeated several times until each inkjet head 330 discharges accurate droplets.

For example, in the setting of the inkjet printing apparatus 1000, in case that the setting of the reference set value is completed, the ink 90 in which the bipolar elements 95 are dispersed may be prepared in the ink circulation unit 600, and may be supplied to the inkjet head 330. The ink circulation unit 600 and the inkjet head 330 may be maintained so that the bipolar elements 95 in the ink 90 have a uniform dispersion degree by the ink circulation system.

However, embodiments are not limited thereto, and the setting (S100) of the inkjet printing apparatus described above may also be omitted.

In case that the setting of the inkjet printing apparatus 1000 is completed, the target substrate SUB may be prepared, referring to FIG. 25. In an embodiment, a first electrode 21 and a second electrode 22 may be disposed on the target substrate SUB. For example, a pair of electrodes may be disposed, but larger pairs of electrodes may be formed on the target substrate SUB, and inkjet heads 330 may jet (or spray) the ink 90 onto each pair of electrodes in the same manner.

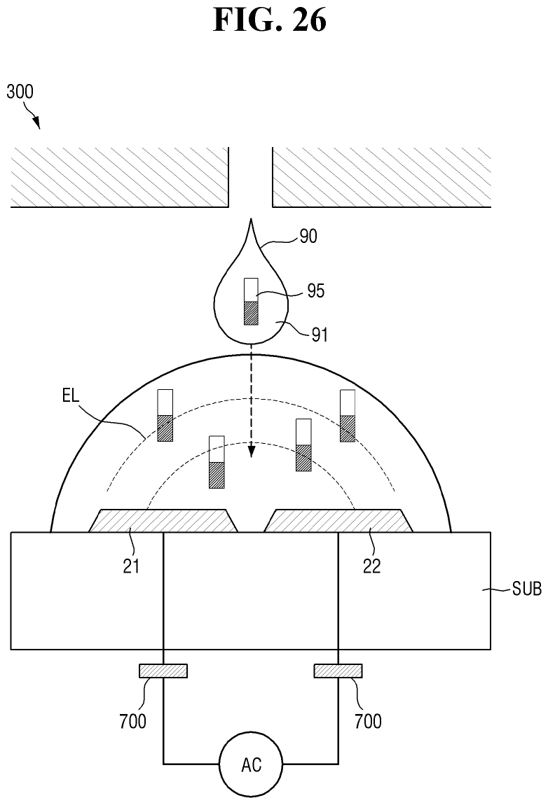

Referring to FIG. 26, the ink 90 including the solvent 91 in which the bipolar elements 95 are dispersed is jetted (or sprayed) onto the target substrate SUB. The ink 90 may be discharged (or sprayed) from the inkjet head 330, and may be jetted onto the first electrode 21 and the second electrode 22 disposed on the target substrate SUB. The ink 90 may be jetted onto the first electrode 21 and the second electrode 22 disposed on the target substrate SUB, and the bipolar elements 95 dispersed in the ink 90 may be jetted onto the target substrate SUB in a state in which the bipolar elements 95 extend in a direction.

In an embodiment, before the jetting of the ink 90 onto the electrodes 21 and 22, the electric field generating device 700 may be electrically connected to the electrodes 21 and 22 of the target substrate SUB and may generate the electric field EL on the electrodes 21 and 22 of the target substrate SUB. Accordingly, the ink 90 may be jetted onto the target substrate SUB on which the electric field EL is generated. In case that the target substrate SUB is prepared (or provided) on the stage STA, the electric field generating device 700 may be electrically connected to the electrodes 21 and 22 on the target substrate SUB. Pad parts connected to the electrodes 21 and 22 are disposed on the target substrate SUB, and the probe driver 703 of the electric field generating device 700 moves, such that the probe pad 708 and the pad parts may be in contact with each other. Before the stage STA moves to the inkjet device 300 and the ink 90 is jetted onto the target substrate SUB, the electric field generating device 700 may generate the electric field EL on the target substrate SUB, and the ink 90 may pass through the electric field EL and be then jetted onto the electrodes 21 and 22.

However, embodiments are not limited thereto, and the electric field generating device 700 may also be connected (e.g., electrically connected) to the target substrate SUB and may generate the electric field EL on the target substrate SUB, after the inkjet device 300 discharges the ink 90.

The bipolar elements 95 included in the ink 90 may be oriented on the target substrate SUB by the electric field EL to have the initial positions and the initial orientation directions. In some embodiments, the bipolar elements 95 may be disposed on the first electrode 21 and the second electrode 22 by receiving a dielectrophoretic force transferred by the electric field EL generated on the target substrate SUB. As described above, the bipolar elements 95 may have the initial positions and the initial orientation directions by the electric field EL. The initial positions and the initial orientation directions of the bipolar elements 95 may be changed by the light irradiation process of irradiating the target substrate SUB with the light hv to have the final positions and the final orientation directions. Thus, the bipolar elements 95 may be more effectively and accurately aligned on the first electrode 21 and the second electrode 22.

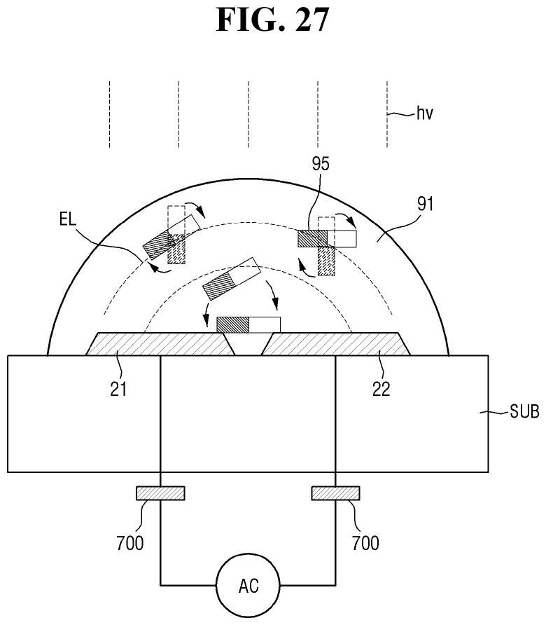

Referring to FIG. 27, in case that the light irradiation device 500 irradiates the target substrate SUB with the light hv, dipole moments of the bipolar elements 95 may increase in response to the light hv. In an embodiment, in case that the light irradiation device 500 irradiates the target substrate SUB with the light hv, directions toward which the first end portions of at least some of the bipolar elements 95 are directed (or oriented) may change by the electric field EL. The bipolar elements 95 having the increased dipole moments may be oriented so that the first end portions may be directed (or oriented) toward a constant direction, in response to the electric field EL generated on the electrodes 21 and 22. At the same time, at least one end portion of the bipolar elements 95 may be disposed on the first electrode 21 or the second electrode 22. For example, the first end portions of the bipolar elements 95 may be disposed on the first electrode 21, and the second end portions of the bipolar elements 95 may be disposed on the second electrode 22. However, embodiments are not limited thereto, and some bipolar elements 95 may be disposed (e.g., directly disposed) on the target substrate SUB between the first electrode 21 and the second electrode 22.

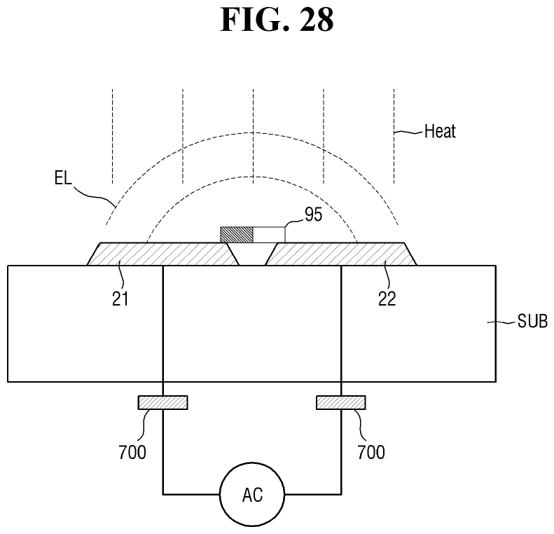

Referring to FIG. 28, the solvent 91 of the ink 90 jetted onto the target substrate SUB may be removed. The removing of the solvent 91 may be performed through the drying device 800, and as described above, in order to prevent the misalignment of the bipolar elements 95, the electric field generating device 700 may generate the electric field EL on the target substrate SUB even during the drying process. The solvent 91 may be removed from the ink 90 jetted onto the target substrate SUB, such that positions of the bipolar elements 95 may be fixed, and the bipolar elements 95 may be seated on the electrodes 21 and 22.

In the printing method of a bipolar element 95 according to an embodiment, the bipolar elements 95 may be seated on the electrodes 21 and 22 disposed on the target substrate SUB by using the inkjet printing apparatus 1000 of FIG. 1.

For example, the inkjet printing apparatus 1000 may include the inspection device 900, and the printing method of a bipolar element 95 may further include measuring a degree of alignment of the bipolar elements 95 disposed on the electrodes 21 and 22.

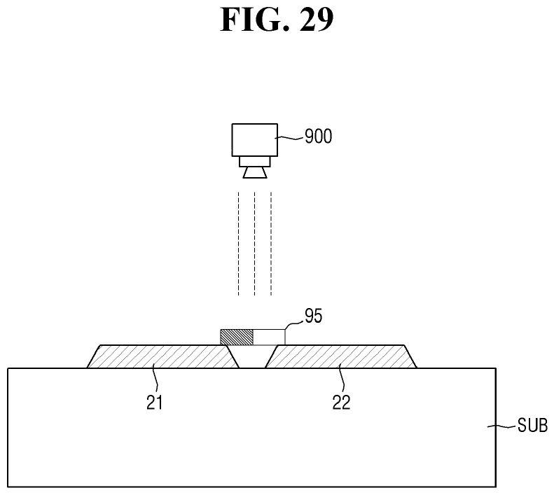

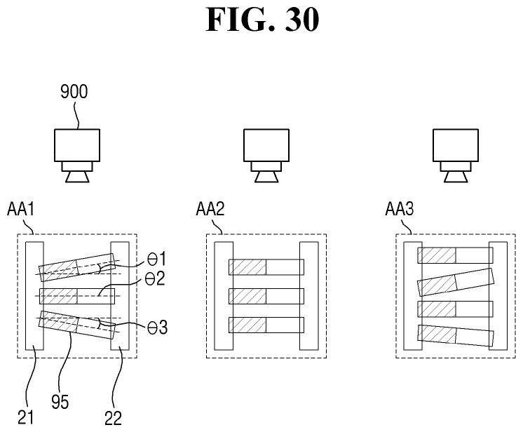

FIGS. 29 and 30 are schematic views illustrating inspecting bipolar elements 95 printed on a target substrate SUB according to an embodiment.

Referring to FIGS. 29 and 30, the printing method of a bipolar elements 95 may include measuring the number and positions of bipolar elements 95 disposed on the target substrate SUB by using the inspection device 900. The sensing unit 950 of the inspection device 900 may measure the number of bipolar elements 95 disposed in unit regions AA1, AA2, and AA3 (see FIG. 30) defined on the target substrate SUB or measure orientation directions of the bipolar elements 95 disposed on the electrodes 21 and 22.

First, the sensing unit 950 may measure the number of bipolar elements 95 disposed in unit regions AA1, AA2, and AA3. In the drawing, a first region AA1, a second region AA2, and a third region AA3 defined as arbitrary regions are illustrated. The sensing unit 950 may measure the number of the bipolar elements 95 disposed in each of the unit regions AA1, AA2, and AA3 and compare the number of the bipolar elements 95 with a reference set value. In case that an error occurs in the number of bipolar elements 95 disposed in each of the unit regions AA1, AA2, and AA3 as compared with the reference set value, the number of bipolar elements 95 may be adjusted by feeding back the error. For example, the inkjet printing apparatus 1000 may adjust the number of bipolar elements 95 disposed in each of the unit regions AA1, AA2, and AA3 by adjusting a dispersion degree of the bipolar elements 95 in the ink 90 discharged from the inkjet head 330 of the inkjet device 300.

For example, the sensing unit 950 may measure the degree of alignment of the bipolar elements 95 by measuring the positions and the orientation directions of the bipolar elements 95 disposed on the first electrode 21 and the second electrode 22. For example, in case that the electrodes 21 and 22 disposed on the target substrate SUB have a shape in which they extend in a direction and the bipolar elements 95 are disposed between the electrodes 21 and 22, acute angles θ1, θ2, and θ3 formed between a direction in which the bipolar elements 95 extend and a direction perpendicular to the direction in which the electrodes 21 and 22 extend may be measured. In some cases, the sensing unit 950 may measure positions of end portions (e.g., opposite end portions) of the bipolar elements 95 to confirm whether or not the end portions are disposed on the electrodes 21 and 22. The inkjet printing apparatus 1000 may measure the degree of alignment of the bipolar elements 95 by comparing the measured acute angles and the positions of the end portions of the bipolar elements 95 with reference set values. In case that an error occurs in the degree of alignment of the bipolar elements 95 as compared with the reference set value, the degree of alignment of the bipolar elements 95 may be adjusted by feeding back the error. For example, the inkjet printing apparatus 1000 may adjust the degree of adjustment of the bipolar elements 95 by adjusting a strength of the electric field EL generated by the electric field generating device 700, an amount of light hv irradiated from the light irradiation device 500, or the like.

In the printing method of a bipolar element 95 according to an embodiment, the bipolar elements 95 may be disposed and aligned at desired positions on the target substrate SUB by by using the inkjet printing apparatus 1000. During the printing process, the electric field generating device 700 may continuously generate the electric field EL during an ink jetting process, the light irradiation process, and the drying process. According to an embodiment, the bipolar elements 95 may be printed with a high degree of alignment on the target substrate SUB by using the inkjet printing apparatus 1000.

For example, the above-described bipolar element 95 may be a light emitting element including semiconductor layers, and according to an embodiment, a display device 10 including the light emitting elements may be manufactured by using the inkjet printing apparatus 1000.

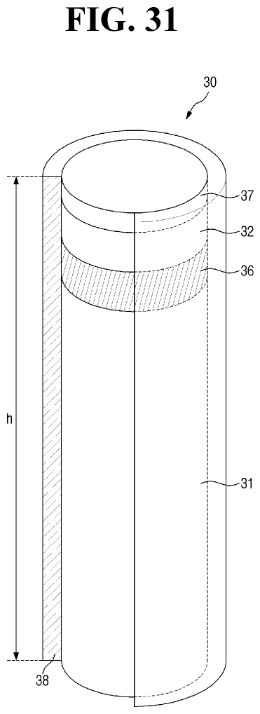

FIG. 31 is a schematic view of a light emitting element 30 according to an embodiment.

The light emitting element 30 may be a light emitting diode. For example, the light emitting element 30 may be an inorganic light emitting diode having a size of a micrometer or nanometer scale and made of an inorganic material. The inorganic light emitting diodes may be aligned between two electrodes in which polarities are formed in case that an electric field is formed in a specific direction between the two electrodes facing each other. The light emitting elements 30 may be aligned between the two electrodes by the electric field formed on the two electrodes.

The light emitting element 30 according to an embodiment may have a shape in which the light emitting element 30 extends in a direction. The light emitting element 30 may have a shape such as a rod shape, a wire shape, or a tube shape. In an embodiment, the light emitting element 30 may have a cylindrical shape or a rod shape. However, the light emitting element 30 is not limited to having the shape described above, and may have various shapes. For example, the light emitting element 30 may have a polygonal prismatic shape such as a cubic shape, a rectangular parallelepiped shape, or a hexagonal prismatic shape or have a shape in which the light emitting element 30 extends in a direction, but outer surfaces of the light emitting element 30 may be inclined (e.g., partially inclined). Semiconductors included in a light emitting element 30 to be described below may have a structure in which they are sequentially disposed or stacked along the direction.

The light emitting element 30 may include a semiconductor layer doped with any conductivity-type impurities (e.g., a p-type dopant or an n-type dopant). The semiconductor layer may receive an electrical signal applied from an external power source to emit light of a specific wavelength band.

Referring to FIG. 31, the light emitting element 30 may include a first semiconductor layer 31, a second semiconductor layer 32, an active layer 36, an electrode layer 37, and an insulating film 38.

The first semiconductor layer 31 may be an n-type semiconductor. As an example, in case that the light emitting element 30 emits light of a blue wavelength band, the first semiconductor layer 31 may include a semiconductor material having a chemical formula of AlₓGayIn_{1-x-y}N (0≤x≤1, 0≤y≤1, and 0≤x+y≤1). For example, the semiconductor material may be one or more of AlGaInN, GaN, AlGaN, InGaN, AlN, and InN doped with an n-type dopant. The first semiconductor layer 31 may be doped with an n-type dopant, which may be Si, Ge, Sn, or the like, as an example. In an embodiment, the first semiconductor layer 31 may be made of n-GaN doped with n-type Si. A length of the first semiconductor layer 31 may be in the range of about 1.5 μm to about 5 μm, but embodiments are not limited thereto.

The second semiconductor layer 32 may be disposed on an active layer 36 to be described below. The second semiconductor layer 32 may be a p-type semiconductor, and as an example, in case that the light emitting element 30 emits light of a blue or green wavelength band, the second semiconductor layer 32 may include a semiconductor material having a chemical formula of AlₓGayIn_{1-x-y}N (0≤x≤1, 0≤y≤1, and 0≤x+y≤1). For example, the semiconductor material may be one or more of AlGaInN, GaN, AlGaN, InGaN, AlN, and InN doped with a p-type dopant. The second semiconductor layer 32 may be doped with a p-type dopant, which may be Mg, Zn, Ca, Se, Ba, or the like, as an example. In an embodiment, the second semiconductor layer 32 may be made of p-GaN doped with p-type Mg. A length of the second semiconductor layer 32 may be in the range of about 0.05 μm to about 0.10 μm, but embodiments are not limited thereto.

For example, each of the first semiconductor layer 31 and the second semiconductor layer 32 may be formed as a layer, but embodiments are not limited thereto. According to some embodiments, each of the first semiconductor layer 31 and the second semiconductor layer 32 may further include a larger number of layers (e.g., a clad layer or a tensile strain barrier reducing (TSBR) layer) according to a material of the active layer 36.

The active layer 36 may be disposed between the first semiconductor layer 31 and the second semiconductor layer 32. The active layer 36 may include a material having a single quantum well structure or a multiple quantum well structure. In case that the active layer 36 includes the material having the multiple quantum well structure, the active layer 36 may have a structure in which quantum layers and well layers are alternately stacked. The active layer 36 may emit light by a combination of electron-hole pairs according to electrical signals applied through the first semiconductor layer 31 and the second semiconductor layer 32. As an example, in case that the active layer 36 emits light of a blue wavelength band, the active layer 36 may include a material such as AlGaN or AlGaInN. In case that the active layer 36 has the multiple quantum well structure (e.g., the structure in which the quantum layers and the well layers) may be alternately stacked, the quantum layers may include a material such as AlGaN or AlGaInN, and the well layers may include a material such as GaN or AlInN. In an embodiment, the active layer 36 may include AlGaInN as a material of the quantum layers and AlInN as a material of the well layers to emit blue light having a central wavelength band of about 450 nm to about 495 nm, as described above.

However, embodiments are not limited thereto, and the active layer 36 may have a structure in which semiconductor materials having large band gap energy and semiconductor materials having small band gap energy are alternately stacked, and may include other Group III to Group V semiconductor materials according to a wavelength band of emitted light. The light emitted by the active layer 36 is not limited to the light of the blue wavelength band, and in some case, the active layer 36 may emit light of red and green wavelength bands. A length of the active layer 36 may be in the range of about 0.05 μm to about 0.10 μm, but embodiments are not limited thereto.

For example, the light emitted from the active layer 36 may be emitted not only to outer surfaces of the light emitting element 30 in a length direction, but also to side surfaces (e.g., opposite side surfaces) of the light emitting element 30. The transmission direction of the light emitted from the active layer 36 is not limited thereto.

The electrode layer 37 may be an ohmic connection electrode. However, embodiments are not limited thereto, and the electrode layer 37 may also be a Schottky connection electrode. The light emitting element 30 may include at least one electrode layer 37. Referring to FIG. 31, the light emitting element 30 may include an electrode layer 37, but embodiments are not limited thereto. In some cases, the light emitting element 30 may also include a larger number of electrode layers 37 or the electrode layer 37 may also be omitted. A description of a light emitting element 30 to be provided below may be applied even though the number of electrode layers 37 is changed or the light emitting element 30 may further include another structure.

The electrode layer 37 may decrease resistance between the light emitting element 30 and the electrode or the connection electrode in case that the light emitting element 30 is connected (e.g., electrically connected) to the electrode or the connection electrode in a display device 10 according to an embodiment. The electrode layer 37 may include a metal having conductivity. The electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). The electrode layer 37 may include a semiconductor material doped with an n-type or p-type dopant.

The insulating film 38 may be disposed to surround outer surfaces of the semiconductor layers and the electrode layers described above. In an embodiment, the insulating film 38 may surround at least an outer surface of the active layer 36, and may extend in a direction in which the light emitting element 30 extends. The insulating film 38 may protect these members. As an example, the insulating film 38 may surround side surface portions of these members, but may expose end portions of the light emitting element 30 in the length direction.

For example, the insulating film 38 may extend in the length direction of the light emitting element 30 to cover side surfaces of the first semiconductor layer 31 to the electrode layer 37, but embodiments are not limited thereto. The insulating film 38 may cover only outer surfaces of some of the semiconductor layers as well as the active layer 36 or may cover only a portion of an outer surface of the electrode layer 37, such that the outer surface of each electrode layer 37 may be exposed (e.g., partially exposed). For example, the insulating film 38 may also be formed so that an upper surface of the insulating film 38 may be rounded in cross section in an area adjacent to at least one end portion of the light emitting element 30.

A thickness of the insulating film 38 may be in the range of about 10 nm to about 1.0 μm, but embodiments are not limited thereto. For example, the thickness of the insulating film 38 may be about 40 nm.

The insulating film 38 may include materials having insulating properties, such as silicon oxide (SiOₓ), silicon nitride (SiNₓ), silicon oxynitride (SiOₓN_{y}), aluminum nitride (AlNₓ), and aluminum oxide (AlOₓ). Accordingly, an electrical short circuit that may occur in case that the active layer 36 is in direct contact with an electrode through which an electrical signal is transferred to the light emitting element 30 may be prevented. For example, the insulating film 38 may protect an outer surface of the light emitting element 30 as well as the active layer 36, and may thus prevent a decrease in luminous efficiency.

For example, in some embodiments, an outer surface of the insulating film 38 may be surface-treated. The light emitting elements 30 may be jetted onto electrodes in a state in which they are dispersed in ink and be aligned. In order to maintain the light emitting elements 30 in a state in which the light emitting elements 30 are dispersed without being agglomerated with other adjacent light emitting elements 30 in the ink, a hydrophobic or hydrophilic treatment may be performed on a surface of the insulating film 38.

The light emitting element 30 may have a length h in the range of about 1 μm to about 10 μm or in the range of about 2 μm to about 6 μm. For example, the light emitting element 30 may have the length h in the range of about 3 μm to about 5 μm. For example, a diameter of the light emitting element 30 may be in the range of about 30 nm to about 700 nm, and an aspect ratio of the light emitting element 30 may be about 1.2 to about 100. However, embodiments are not limited thereto, and light emitting elements 30 included in the display device 10 may also have different diameters according to a difference in composition between the active layers 36. For example, the diameter of the light emitting element 30 may be about 500 nm.

According to an embodiment, the inkjet printing apparatus 1000 may disperse the light emitting elements 30 of FIG. 31 in the ink 90 and may jet or discharge the ink 90 in which the light emitting elements 30 are dispersed onto the target substrate SUB to manufacture the display device 10 including the light emitting elements 30.

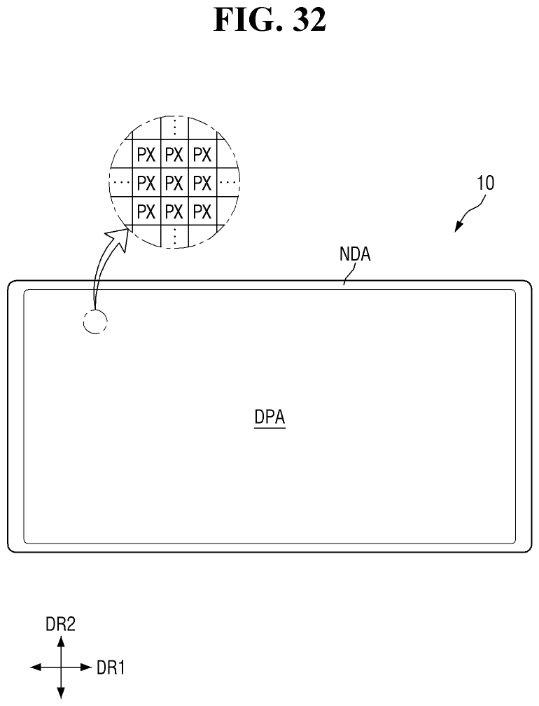

FIG. 32 is a schematic plan view of a display device 10 according to an embodiment.

Referring to FIG. 32, the display device 10 may display a moving image or a still image. The display device 10 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the display device 10.

The display device 10 may include a display panel providing the display screen. Examples of the display panel may include an inorganic light emitting diode display panel, an organic light emitting display panel, a quantum dot light emitting display panel, a plasma display panel, a field emission display panel, and the like. Hereinafter, a case where an inorganic light emitting diode display panel is applied as an example of the display panel will be described by way of example, but embodiments are not limited thereto, and other display panels may be applied thereto.

A shape of the display device 10 may be variously modified. For example, the display device 10 may have a shape such as a rectangular shape with a width greater than a length, a rectangular shape with a length greater than a width, a square shape, a rectangular shape with rounded corners (e.g., vertices), other polygonal shapes, or a circular shape. A shape of a display area DPA of the display device 10 may also be similar to an overall shape of the display device 10. Referring to FIG. 1, the display device 10 and the display area DPA may have the rectangular shape with the width greater than the length.

The display device 10 may include a display area DPA and non-display areas NDA. The display area DPA may be an area in which an image is displayed, and the non-display area NDA may be an area in which any image is not displayed. The display area DPA may also be referred to as an active area, and the non-display area NDA may also be referred to as a non-active area. The display area DPA may occupy substantially the center of the display device 10.

The display area DPA may include pixels PX. The pixels PX may be arranged in a matrix direction. A shape of each pixel PX may be a rectangular shape or a square shape in a plan view, but embodiments are not limited thereto, and may also be a rhombic shape of which each side is inclined with respect to a direction. The respective pixels PX may be alternately arranged in a stripe type or a PenTile® type. For example, each of the pixels PX may include one or more light emitting elements 30 emitting light of a specific wavelength band to display a specific color.

The non-display areas NDA may be disposed around the display area DPA. The non-display areas NDA may entirely or partially surround the display area DPA. The display area DPA may have a rectangular shape, and the non-display areas NDA may be disposed adjacent to four sides of the display area DPA. The non-display areas NDA may form a bezel of the display device 10. Lines or circuit drivers included in the display device 10 may be disposed or external devices may be mounted, in each of the non-display areas NDA.

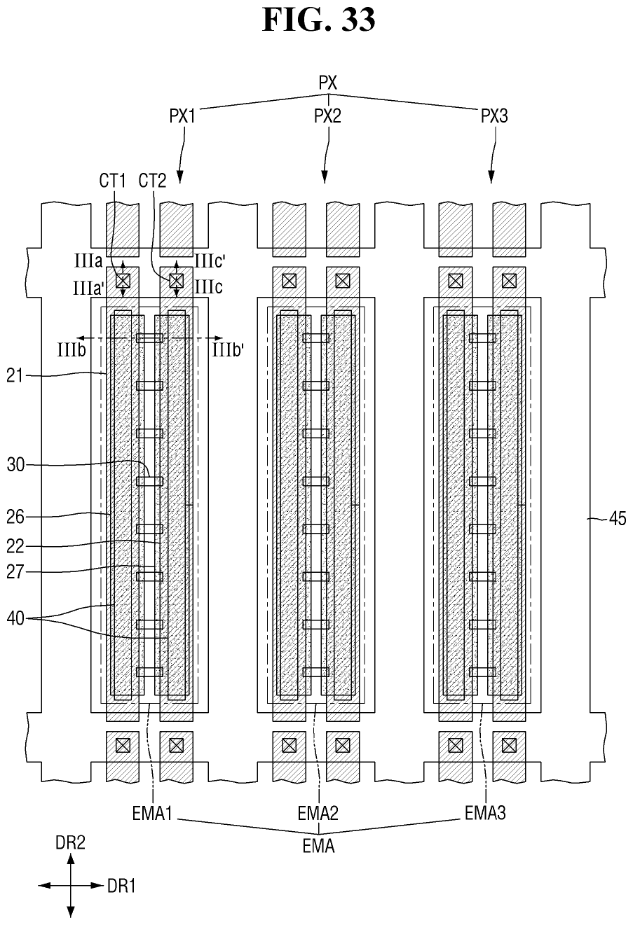

FIG. 33 is a schematic plan view illustrating a pixel PX of the display device 10 according to an embodiment.

Referring to FIG. 33, each of the pixels PX may include sub-pixels PXn (where n is an integer of 1 to 3). For example, each pixel PX may include a first sub-pixel PX1, a second sub-pixel PX2, and a third sub-pixel PX3. The first sub-pixel PX1 may emit light of a first color, the second sub-pixel PX2 may emit light of a second color, and the third sub-pixel PX3 may emit light of a third color. The first color may be blue, the second color may be green, and the third color may be red. However, embodiments are not limited thereto, and the respective sub-pixels PXn may also emit light of the same color. For example, referring to FIG. 2, the pixel PX may include three sub-pixels PXn, but embodiments are not limited thereto, and the pixel PX may include a larger number of sub-pixels PXn.

Each of the sub-pixels PXn of the display device 10 may include an area defined as an emission area EMA. The first sub-pixel PX1 may include a first emission area EMA1, the second sub-pixel PX2 may include a second emission area EMA2, and the third sub-pixel PX3 may include a third emission area EMA3. The emission area EMA may be defined as an area in which the light emitting elements 30 included in the display device 10 are disposed to emit light of a specific wavelength band. The active layer 36 of the light emitting element 30 may emit light of a specific wavelength band without any specific transmission direction, and the light may be emitted toward side surfaces (e.g., opposite side surfaces) of the light emitting element 30. The emission area EMA may include an area in which the light emitting elements 30 are disposed, and may include an area in which the light emitted from the light emitting elements 30 is emitted, as an area adjacent to the light emitting elements 30.

Embodiments are not limited thereto, and the emission area EMA may also include an area in which the light emitted from the light emitting elements 30 is reflected or refracted by other members and then emitted. Light emitting elements 30 may be disposed in each sub-pixel PXn, and the emission area EMA including an area in which the light emitting elements 30 are disposed and an area adjacent to the light emitting elements 30 may be formed.

For example, each of the sub-pixels PXn of the display device 10 may include a non-emission area defined as an area other than the emission area EMA. The non-emission area may be an area in which the light emitting elements 30 are not disposed and the light emitted from the light emitting elements 30 may not be transmitted, and thus, the light may not be emitted.

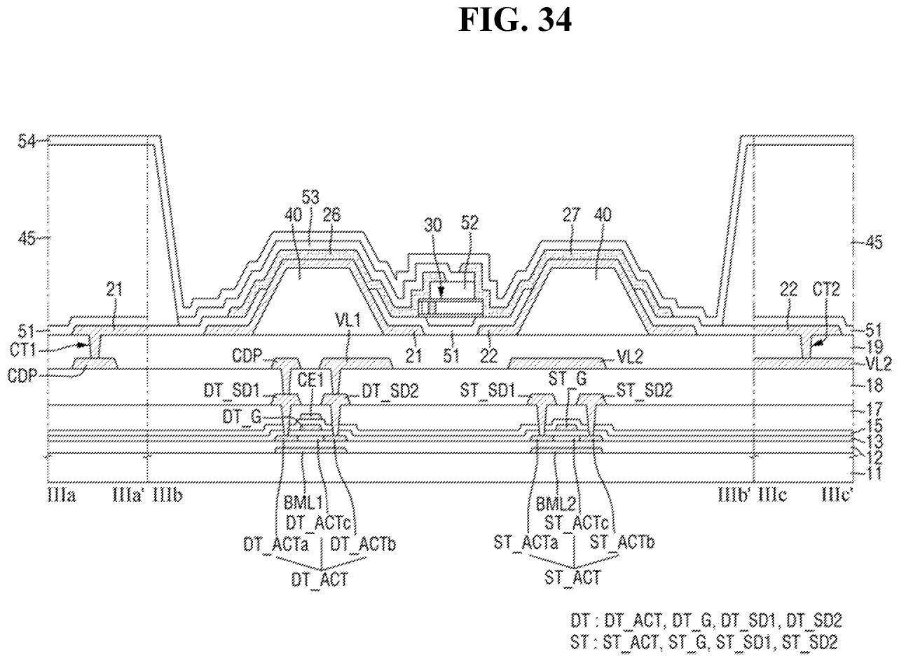

FIG. 34 is a schematic cross-sectional view taken along line line and line IIIc-IIIc′ of FIG. 33. FIG. 34 illustrates only a cross section of the first sub-pixel PX1 of FIG. 3, but may be applied to other pixels PX or sub-pixels PXn. FIG. 34 illustrates a cross section crossing an end portion and another end portion of the light emitting element 30 disposed in the first sub-pixel PX1.

Referring to FIG. 34 in conjunction with FIG. 33, the display device 10 may include a first substrate 11, and a semiconductor layer, conductive layers, and insulating layers disposed on the first substrate 11.

For example, the first substrate 11 may be an insulating substrate. The first substrate 11 may be made of an insulating material such as glass, quartz, or a polymer resin. For example, the first substrate 11 may be a rigid substrate, but may also be a flexible substrate that may be bent, folded, or rolled.

A first conductive layer may be disposed on the first substrate 11. The first conductive layer may include first and second lower metal layers BML1 and BML2. For example, the first lower metal layer BML1 and the second lower metal layer BML2 of the first and second lower metal layers BML1 and BML2 may overlap at least active material layers DT_ACT and ST_ACT of a driving transistor DT and a switching transistor ST, respectively. The first and second lower metal layers BML1 and BML2 may include a light blocking material to prevent light from being incident on the active material layers DT_ACT and ST_ACT of the respective transistors as an example, the first and second lower metal layers BML1 and BML2 may be made of an opaque metal material blocking transmission of the light. However, embodiments are not limited thereto, and in some cases, the first and second lower metal layers BML1 and BML2 may be omitted or only the first lower metal layer BML1 may be included.

A buffer layer 12 may be disposed (e.g., entirely disposed) on the first conductive layer and the first substrate 11. The buffer layer 12 may be formed on the first substrate 11 in order to protect the transistors DT and ST of the pixel PX from moisture permeating through the first substrate 11 vulnerable to moisture permeation, and may perform a surface planarization function. The buffer layer 12 may include inorganic layers that are alternately stacked. For example, the buffer layer 12 may be formed as a double layer in which inorganic layers including at least one of silicon oxide (SiOₓ), silicon nitride (SiNₓ), and silicon oxynitride (SiOₓN_{y}) are stacked or multiple layers in which these layers are alternately stacked.

The semiconductor layer may be disposed on the buffer layer 12. The semiconductor layer may include a first active material layer DT_ACT of the driving transistor DT and a second active material layer ST_ACT of the switching transistor ST. The first active material layer DT_ACT and the second active material layer ST_ACT may overlap (e.g., partially overlap) gate electrodes DT_G and ST_G or the like of a second conductive layer to be described below.

In an embodiment, the semiconductor layer may include polycrystalline silicon, single crystal silicon, an oxide semiconductor, or the like. The polycrystalline silicon may be formed by crystallizing amorphous silicon. In case that the semiconductor layer includes the polycrystalline silicon, the first active material layer DT_ACT may include doped regions DT_ACTa and DT_ACTb doped with impurities and a channel region DT_ACTc disposed between the doped regions DT_ACTa and DT_ACTb. The second active material layer ST_ACT may also include doped regions ST_CTa and ST_CTb and a channel region ST_ACTc disposed between the doped regions ST_ACTa and ST_ACTb.

In an embodiment, the semiconductor layer may include an oxide semiconductor. For example, the doped regions of the respective active material layers DT_ACT and ST_ACT may be conductive regions. The oxide semiconductor may be an oxide semiconductor containing indium (In). In some embodiments, the oxide semiconductor may be indium tin oxide (ITO), indium zinc oxide (IZO), indium gallium oxide (IGO), indium zinc tin oxide (IZTO), indium gallium tin oxide (IGTO), indium gallium zinc oxide (IGZO), indium gallium zinc tin oxide (IGZTO), or the like. However, embodiments are not limited thereto.

A first gate insulating layer 13 may be disposed on the semiconductor layer and the buffer layer 12. The first gate insulating layer 13 may function as a gate insulating film of each of transistors DT and ST. The first gate insulating layer 13 may be formed as a double layer in which inorganic layers including an inorganic material, for example, at least one of silicon oxide (SiOₓ), silicon nitride (SiNₓ), and silicon oxynitride (SiOₓN_{y}) may be stacked or multiple layers in which these layers are alternately stacked.

A second conductive layer may be disposed on the first gate insulating layer 13. The second conductive layer may include a first gate electrode DT_G of the driving transistor DT and a second gate electrode ST_G of the switching transistor ST. The first gate electrode DT_G may overlap a first channel region DT_ACTc of the first active material layer DT_ACT in a thickness direction, and the second gate electrode ST_G may overlap a second channel region ST_ACTc of the second active material layer ST_ACT in the thickness direction. The second conductive layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments are not limited thereto.

A first passivation layer 15 may be disposed on the second conductive layer. The first passivation layer 15 may cover the second conductive layer to protect the second conductive layer. The first passivation layer 15 may be formed as a double layer in which inorganic layers including an inorganic material, for example, at least one of silicon oxide (SiOₓ), silicon nitride (SiNₓ), and silicon oxynitride (SiOₓN_{y}) may be stacked or multiple layers in which these layers are alternately stacked.

A third conductive layer may be disposed on the first passivation layer 15. The third conductive layer may include a first capacitor electrode CE1 of a storage capacitor of which at least a partial area is disposed to overlap the first gate electrode DT_G in the thickness direction. The first capacitor electrode CE1 may overlap the first gate electrode DT_G in the thickness direction with the first passivation layer 15 interposed therebetween, and the storage capacitor may be formed between the first capacitor electrode CE1 and the first gate electrode DT_G. The third conductive layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments are not limited thereto.

A first interlayer insulating layer 17 may be disposed on the third conductive layer. The first interlayer insulating layer 17 may function as an insulating film between the third conductive layer and other layers disposed above the third conductive layer. The first interlayer insulating layer 17 may be formed as a double layer in which inorganic layers including an inorganic material, for example, at least one of silicon oxide (SiOₓ), silicon nitride (SiNₓ), and silicon oxynitride (SiOₓN_{y}) are stacked or multiple layers in which these layers are alternately stacked.

A fourth conductive layer may be disposed on the first interlayer insulating layer 17. The fourth conductive layer may include a first source/drain electrode DT_SD1 and a second source/drain electrode DT_SD2 of the driving transistor DT and a first source/drain electrode ST_SD1 and a second source/drain electrode ST_SD2 of the switching transistor ST.

The source/drain electrodes DT_SD1 and DT_SD2 of the driving transistor DT may be in contact with the doped regions DT_ACTa and DT_ACTb of the first active material layer DT_ACT through contact holes penetrating through the first interlayer insulating layer 17 and the first gate insulating layer 13, respectively. The source/drain electrodes ST_SD1 and ST_SD2 of the switching transistor ST may be in contact with the doped regions ST_ACTa and ST_ACTb of the second active material layer ST_ACT through contact holes penetrating through the first interlayer insulating layer 17 and the first gate insulating layer 13, respectively. For example, the first source/drain electrode DT_SD1 of the driving transistor DT and the first source/drain electrode ST_SD1 of the switching transistor ST may be electrically connected to the first lower metal layer BML1 and the second lower metal layer BML2 through other contact holes, respectively.

The fourth conductive layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments are not limited thereto.

A second interlayer insulating layer 18 may be disposed on the fourth conductive layer. The second interlayer insulating layer 18 may be disposed (e.g., entirely disposed) on the first interlayer insulating layer 17 with covering the fourth conductive layer, and may protect the fourth conductive layer. The second interlayer insulating layer 18 may be formed as a double layer in which inorganic layers including an inorganic material, for example, at least one of silicon oxide (SiOₓ), silicon nitride (SiNₓ), and silicon oxynitride (SiOₓN_{y}) are stacked or multiple layers in which these layers are alternately stacked.

A fifth conductive layer may be disposed on the second interlayer insulating layer 18. The fifth conductive layer may include a first voltage line VL1, a second voltage line VL2, and a first conductive pattern CDP. A high potential voltage (or a first source voltage) supplied to the driving transistor DT may be applied to the first voltage line VL1, and a low potential voltage (or a second source voltage) supplied to a second electrode 22 may be applied to the second voltage line VL2. For example, an alignment signal for aligning light emitting elements 30 may be applied to the second voltage line VL2 in processes of manufacturing the display device 10.

The first conductive pattern CDP may be electrically connected to the first source/drain electrode DT_SD1 of the driving transistor DT through a contact hole formed in the second interlayer insulating layer 18. The first conductive pattern CDP may also be in contact with a first electrode 21 to be described below, and the driving transistor DT may transfer the first source voltage applied from the first voltage line VL1 to the first electrode 21 through the first conductive pattern CDP. For example, the fifth conductive layer may include a second voltage line VL2 and a first voltage line VL1, but embodiments are not limited thereto. The fifth conductive layer may include larger numbers of first voltage lines VL1 and second voltage lines VL2.

The fifth conductive layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments are not limited thereto.

A first planarization layer 19 may be disposed on the fifth conductive layer. The first planarization layer 19 may include an organic insulating material, for example, an organic material such as polyimide (PI), and perform a surface planarization function.

First banks 40, electrodes 21 and 22, light emitting elements 30, a second bank 45, and connection electrodes 26 and 27 may be disposed on the first planarization layer 19. For example, insulating layers 51, 52, 53, and 54 may be further disposed on the first planarization layer 19.

The first banks 40 may be disposed (e.g., directly disposed) on the first planarization layer 19. The first banks 40 may extend in the second direction DR2 within each sub-pixel PXn, but may be spaced apart from each other and terminated (or ended) at boundary areas between the sub-pixels PXn so as not to extend to other sub-pixels PXn neighboring in the second direction DR2. For example, the first banks 40 may be spaced apart from and face each other in the first direction DR1. The first banks 40 may be disposed to be spaced apart from each other, such that an area in which the light emitting elements 30 is disposed may be formed between the first banks 40. The first banks 40 may be disposed for each sub-pixel PXn to form a linear pattern in the display area DPA of the display device 10. Two first banks 40 are illustrated in drawing, but embodiments are not limited thereto. A larger number of first banks 40 may also be further disposed according to the number of electrodes 21 and 22 to be described below.

The first banks 40 may have a structure in which at least portions thereof protrude from an upper surface of the first planarization layer 19. Protruding portions of the first banks 40 may have inclined side surfaces, and light emitted from the light emitting elements 30 may transmit toward the inclined side surfaces of the first banks 40. The electrodes 21 and 22 disposed on the first banks 40 may include a material having high reflectivity, and the light emitted from the light emitting elements 30 may be reflected by the electrodes 21 and 22 disposed on the side surfaces of the first banks 40 and be emitted in an upward direction of the first planarization layer 19. For example, the first banks 40 may function as reflective partition walls reflecting the light emitted from the light emitting elements 30 toward the upward direction with providing the area in which the light emitting elements 30 are disposed. The side surfaces of the first banks 40 may be inclined in a linear shape, but embodiments are not limited thereto, and the first banks 40 may also have a semi-circular shape or a semi-elliptical shape with curved outer surfaces. In an embodiment, the first banks 40 may include an organic insulating material such as polyimide (PI), but embodiments are not limited thereto.

The electrodes 21 and 22 may be disposed on the first banks 40 and the first planarization layer 19. The electrodes 21 and 22 may include a first electrode 21 and a second electrode 22. The first electrode 21 and the second electrode 22 may extend in the second direction DR2, and may be spaced apart from and face each other in the first direction DR1. The first electrode 21 and the second electrode 22 may have a shape substantially similar to that of the first banks 40, but may have a shape in which a length each of the first and second electrodes 21 and 22 measured in the second direction DR2 is greater than that of the first banks 40.

The first electrode 21 and the second electrode 22 may extend in the second direction DR2 within the sub-pixel PXn, respectively, but may be spaced apart from the other electrodes 21 and 22 at boundary areas with other sub-pixels PXn neighboring in the second direction DR2. In some embodiments, the second bank 45 may be disposed at the boundary areas between the respective sub-pixels PXn, and the electrodes 21 and 22 disposed in the respective sub-pixels PXn neighboring in the second direction DR2 may be spaced apart from each other at portions overlapping the second bank 45. However, embodiments are not limited thereto, and some electrodes 21 and 22 may not be separated from each other for each sub-pixel PXn, and may extend beyond the sub-pixels PXn neighboring in the second direction DR2.

The first electrode 21 may be electrically connected to the driving transistor DT through a first contact hole CT1 at a boundary with the sub-pixel PXn neighboring in the second direction DR2. For example, the first electrode 21 may be disposed to at least partially overlap a portion of the second bank 45 extending in the first direction DR1, and may be in contact with the first conductive pattern CDP through the first contact hole CT1 penetrating through the first planarization layer 19. The second electrode 22 may be electrically connected to the second voltage line VL2 through a second contact hole CT2 at a boundary with the sub-pixel PXn neighboring in the second direction DR2. For example, the second electrode 22 may overlap a portion of the second bank 45 extending in the first direction DR1, and may be in contact with the second voltage line VL2 through the second contact hole CT2 penetrating through the first planarization layer 19. However, embodiments are not limited thereto. In some embodiments, the first contact hole CT1 and the second contact hole CT2 may also be disposed in an area surrounded by the second bank 45 so as not to overlap the second bank 45.

For example, a first electrode 21 and a second electrode 22 may be disposed for each sub-pixel PXn, but embodiments are not limited thereto. In some embodiments, the numbers of first electrodes 21 and second electrodes 22 disposed for each sub-pixel PXn may be greater than those illustrated in the drawing. For example, the first electrode 21 and the second electrode 22 disposed in each sub-pixel PXn may not have a shape in which they extend in a direction, and the first electrode 21 and the second electrode 22 may be disposed in various structures. For example, the first electrode 21 and the second electrode 22 may have a partially curved or bent shape, and any one of the first electrode 21 and the second electrode 22 may surround the other of the first electrode 21 and the second electrode 22. The first electrode 21 and the second electrode 22 are not limited in arrangement structures and shapes thereof as long as at least partial areas thereof are spaced apart from and face each other and accordingly, an area in which the light emitting elements 30 are to be disposed is formed between the first electrode 21 and the second electrode 22.

The electrodes 21 and 22 may be electrically connected to the light emitting elements 30, and may receive a voltage applied thereto so that the light emitting elements 30 emits light. For example, the electrodes 21 and 22 may be electrically connected to the light emitting elements 30 through connection electrodes 26 and 27 to be described below, and electrical signals applied to the electrodes 21 and 22 may be transferred to the light emitting elements 30 through the connection electrodes 26 and 27.

Each of the electrodes 21 and 22 may be utilized to generate an electric field in the sub-pixel PXn in order to align the light emitting elements 30. The light emitting elements 30 may be disposed between the first electrode 21 and the second electrode 22 by an electric field formed on the first electrode 21 and the second electrode 22. In a case of using the above-described inkjet printing apparatus 1000, ink including the light emitting elements 30 may be jetted onto each of the electrodes 21 and 22, and the electric field generating device 700 may be electrically connected to each of the electrodes 21 and 22 to generate the electric field EL on each of the electrodes 21 and 22. The light emitting elements 30 dispersed in the ink may be aligned on the electrodes 21 and 22 by receiving a dielectrophoretic force by the electric field EL generated on the electrodes 21 and 22.

The first electrode 21 and the second electrode 22 may be disposed on the first banks 40, respectively. The first electrode 21 and the second electrode 22 may be spaced apart from and face each other in the first direction DR1, and light emitting elements 30 may be disposed between the first electrode 21 and the second electrode 22. The light emitting elements 30 may be disposed between the first electrode 21 and the second electrode 22, and at least one end portion of the light emitting elements 30 may be electrically connected to the first electrode 21 and the second electrode 22.

In some embodiments, the first electrode 21 and the second electrode 22 may have a width greater than that of the first banks 40, respectively. For example, the first electrode 21 and the second electrode 22 may cover outer surfaces of the first banks 40, respectively. The first electrode 21 and the second electrode 22 may be disposed on the side surfaces of the first banks 40, respectively, and a distance between the first electrode 21 and the second electrode 22 may be smaller than a distance between the first banks 40. For example, at least partial areas of the first electrode 21 and the second electrode 22 may be disposed (e.g., directly disposed) on the first planarization layer 19.

Each of the electrodes 21 and 22 may include a transparent conductive material. As an example, each of the electrodes 21 and 22 may include a material such as indium tin oxide (ITO), indium zinc oxide (IZO), or indium tin zinc oxide (ITZO), but embodiments are not limited thereto. In some embodiments, each of the electrodes 21 and 22 may include a conductive material having high reflectivity. For example, each of the electrodes 21 and 22 may include a metal such as silver (Ag), copper (Cu), or aluminum (Al) as the material having the high reflectivity. For example, each of the electrodes 21 and 22 may reflect the light emitted from the light emitting elements 30 and transmitting toward the side surfaces of the first banks 40 in an upward direction of each sub-pixel PXn.

Embodiments are not limited thereto, and the respective electrodes 21 and 22 may have a structure in which one or more layers made of the transparent conductive material and one or more layers made of the metal having the high reflectivity are stacked or may be formed as a layer including the transparent conductive material and the metal having the high reflectivity. In an embodiment, each of the electrodes 21 and 22 may have a stacked structure of ITO/silver (Ag)/ITO/, ITO/Ag/IZO, or ITO/Ag/ITZO/IZO or be made of an alloy including aluminum (Al), nickel (Ni), lanthanum (La), and the like. In another example, each of the electrodes 21 and 22 may have a structure in which a metal layer made of titanium (Ti) and molybdenum (Mo) and the alloy are stacked. In some embodiments, each of the electrodes 21 and 22 may be formed as a double layer or multiple layers in which an alloy including aluminum (Al) and one or more metal layers made of titanium (Ti) or molybdenum (Mo) are stacked.

A first insulating layer 51 may be disposed on the first planarization layer 19, the first electrode 21, and the second electrode 22. The first insulating layer 51 may be disposed to partially cover the first electrode 21 and the second electrode 22 as well as an area between the first electrode 21 and the second electrode 22. For example, the first insulating layer 51 may cover most of upper surfaces of the first electrode 21 and the second electrode 22, but expose portions of the first electrode 21 and the second electrode 22. In other words, the first insulating layer 51 may be formed (e.g., substantially entirely formed) on the first planarization layer 19, but may include openings partially exposing the first electrode 21 and the second electrode 22.

In an embodiment, the first insulating layer 51 may have a step formed so that a portion of an upper surface thereof may be recessed between the first electrode 21 and the second electrode 22. However, embodiments are not limited thereto. The first insulating layer 51 may have a flat upper surface formed so that the light emitting elements 30 may be disposed thereon.

The first insulating layer 51 may insulate the first electrode 21 and the second electrode 22 from each other with protecting the first electrode 210 and the second electrode 220. For example, the first insulating layer 51 may prevent the light emitting elements 30 disposed on the first insulating layer 51 from being in direct contact with and being damaged by other members. However, a shape and a structure of the first insulating layer 51 are not limited thereto.

The second bank 45 may be disposed on the first insulating layer 51. The second bank 45 may surround an area in which the first banks 40 are disposed, on the first insulating layer 51, and may be disposed at boundary areas between the respective sub-pixels PXn. The second bank 45 may have a shape in which the second bank 45 extends in the first direction DR1 and the second direction DR2 to form a lattice-shaped pattern over the entire display area DPA. A portion of the second bank 45 extending in the first direction DR1 may overlap (e.g., partially overlap) the first electrode 21 and the second electrode 22, in case that a portion of the second bank 45 extending in the second direction DR2 may be spaced apart from the first banks 40, the first electrode 21, and the second electrode 22.

According to an embodiment, a height of the second bank 45 may be greater than a height of the first bank 40. Unlike the first bank 40, the second bank 45 may prevent ink from overflowing into adjacent sub-pixels PXn in an inkjet printing process of processes of manufacturing the display device 10 with dividing neighboring sub-pixels PXn. The second bank 45 may separate inks in which different light emitting elements 30 are dispersed for each of different sub-pixels PXn from each other so that these inks may not be mixed with each other. The second bank 45 may include polyimide (PI) like the first bank 40, but embodiments are not limited thereto.

The light emitting elements 30 may be disposed on the respective electrodes 21 and 22. The light emitting elements 30 may be spaced apart from each other, and may be aligned substantially parallel to each other. A distance between the light emitting elements 30 spaced apart from each other is not limited. In some cases, light emitting elements 30 may be disposed adjacent to each other and be grouped, and other light emitting elements 30 may be grouped in a state in which they are spaced apart from each other by a distance and may be disposed with a non-uniform density. For example, a direction in which the respective electrodes 21 and 22 extend and a direction in which the light emitting elements 30 extend may be substantially perpendicular to each other. However, embodiments are not limited thereto, and the light emitting elements 30 may not be perpendicular to the direction in which the respective electrodes 21 and 22 extend, and may also be oblique with respect to the direction in which the respective electrodes 21 and 22 extend.

The light emitting elements 30 may include active layers 36 including different materials to emit light of different wavelength bands to the outside. The display device 10 may include the light emitting elements 30 emitting light of different wavelength bands. For example, the light emitting elements 30 of the first sub-pixel PX1 may include active layers 36 emitting light of a first color of which a central wavelength band is a first wavelength, the light emitting elements 30 of the second sub-pixel PX2 may include active layers 36 emitting light of a second color of which a central wavelength band is a second wavelength, and the light emitting elements 30 of the third sub-pixel PX3 may include active layers 36 emitting light of a third color of which a central wavelength band is a third wavelength. Accordingly, the light of the first color, the light of the second color, and the light of the third color may be emitted from the first sub-pixel PX1, the second sub-pixel PX2, and the third sub-pixel PX3, respectively. However, embodiments are not limited thereto. In some case, the respective sub-pixels PXn may also include the same type of light emitting elements 30 to emit light of substantially the same color.

The light emitting elements 30 may be disposed on the first insulating layer 51 between the first banks 40 or between the respective electrodes 21 and 22. For example, the light emitting elements 30 may be disposed so that at least one end portion of the light emitting elements 30 may be disposed on the first electrode 21 or the second electrode 22. An extension length of the light emitting elements 30 may be greater than the distance between the first electrode 21 and the second electrode 22, and end portions of the light emitting elements 30 may be disposed on the first electrode 21 and the second electrode 22, respectively. However, embodiments are not limited thereto, and only any one end portion of the light emitting elements 30 may be disposed on the electrodes 21 and 22, or end portions of the light emitting elements 30 may not be disposed on the electrodes 21 and 22, respectively. Even though the light emitting elements 30 are not disposed on the electrodes 21 and 22, end portions of the light emitting elements 30 may be connected (e.g., electrically connected) to the electrodes 21 and 22 through connection electrodes 26 and 27 to be described below, respectively.

The light emitting element 30 may include layers disposed in a direction parallel to an upper surface of the first substrate 11 or the first planarization layer 19. The light emitting element 30 of the display device 10 may be disposed so that a direction in which the light emitting element 30 extends is parallel to the first planarization layer 19, and semiconductor layers included in the light emitting element 30 may be sequentially disposed along a direction parallel to the upper surface of the first planarization layer 19. However, embodiments are not limited thereto. In some cases, in case that the light emitting element 30 has another structure, the layers may also be disposed in a direction perpendicular to the first planarization layer 19.

For example, end portions of the light emitting element 30 may be in contact with the connection electrodes 26 and 27, respectively. According to an embodiment, since the insulating film 38 is not formed on end surfaces of the light emitting element 30 in a direction in which the light emitting element 30 extends and portions of the semiconductor layers are exposed, the exposed semiconductor layers may be in contact with the connecting electrodes 26 and 27. However, embodiments are not limited thereto. In some cases, at least partial areas of the insulating film 38 of the light emitting element 30 may be removed and the insulating film 38 may be removed, such that side surfaces of end portions of the semiconductor layers may be exposed (e.g., partially exposed). The exposed side surfaces of the semiconductor layers may also be in direct contact with the connection electrodes 26 and 27.

A second insulating layer 52 may be disposed (e.g., partially disposed) on the light emitting element 30 disposed between the first electrode 21 and the second electrode 22. The second insulating layer 52 may surround (e.g., partially surround) an outer surface of the light emitting element 30. A portion of the second insulating layer 52 disposed on the light emitting element 30 may have a shape in which the second insulating layer 52 extends in the second direction DR2 between the first electrode 21 and the second electrode 22, in a plan view. As an example, the second insulating layer 52 may form a linear or island-shaped pattern within each sub-pixel PXn.

The second insulating layer 52 may be disposed on the light emitting element 30, but may expose an end portion and another end portion of the light emitting element 30. The second insulating layer 52 may fix the light emitting element 30 in a process of manufacturing the display device 10 with protecting the light emitting element 30. For example, in an embodiment, a portion of a material of the second insulating layer 52 may also be disposed between a lower surface of the light emitting element 30 and the first insulating layer 51. As described above, the second insulating layer 52 may also fill a space between the first insulating layer 51 and the light emitting element 30 formed during the process of manufacturing the display device 10. Accordingly, the second insulating layer 52 may surround the outer surface of the light emitting element 30 to fix the light emitting element 30 during the process of manufacturing the display device 10 with protecting the light emitting element 30.

The connection electrodes 26 and 27 and a third insulating layer 53 may be disposed on the second insulating layer 52.

The connection electrodes 26 and 27 may have a shape in which they extend in a direction. The connection electrodes 26 and 27 may be in contact with the light emitting element 30 and the electrodes 21 and 22, respectively. A first connection electrode 26 and a second connection electrode 27 of the connection electrodes 26 and 27 may be disposed on portions of the first electrode 21 and the second electrode 22, respectively. The first connection electrode 26 may be disposed on the first electrode 21, the second connection electrode 27 may be disposed on the second electrode 22, and each of the first connection electrode 26 and the second connection electrode 27 may have a shape in which each of the first connection electrode 26 and the second connection electrode 27 extends in the second direction DR2. The first connection electrode 26 and the second connection electrode 27 may be spaced apart from and face each other in the first direction DR1, and may form a stripe-shaped pattern in the emission area EMA of each sub-pixel PXn.

In some embodiments, widths of the first connection electrode 26 and the second connection electrode 27 measured in a direction may be equal to or smaller than widths of the first electrode 21 and the second electrode 22 measured in the direction, respectively. The first connection electrode 26 and the second connection electrode 27 may cover portions of the exposed upper surfaces of the first electrode 21 and the second electrode 22 with being in contact with an end portion and another end portion of the light emitting element 30, respectively. As described above, portions of the upper surfaces of the first electrode 21 and the second electrode 22 may be exposed, and the exposed upper surfaces of the first electrode 21 and the second electrode 22 may be in contact with the connection electrodes 26 and 27, respectively.

As described above, the light emitting element 30 may have the semiconductor layers exposed on end surfaces (e.g., opposite end surfaces) thereof in the direction in which the light emitting element 30 extends, and the first connection electrode 26 and the second connection electrode 27 may be in contact with the light emitting element 30 on the end surfaces on which the semiconductor layers are exposed. An end portion of the light emitting element 30 may be connected (e.g., electrically connected) to the first electrode 21 through the first connection electrode 26, and another end portion of the light emitting element 30 may be connected (e.g., electrically connected) to the second electrode 22 through the second connection electrode 27.

For example, a single first connection electrode 26 and a single second connection electrode 27 may be disposed in a single sub-pixel PXn, but embodiments are not limited thereto. The numbers of first connection electrodes 26 and second connection electrodes 27 may change according to the numbers of first electrodes 21 and second electrodes 22 disposed in each sub-pixel PXn.

The third insulating layer 53 may be disposed on the first connection electrode 26. The third insulating layer 53 may electrically insulate the first connection electrode 26 and the second connection electrode 27 from each other. The third insulating layer 53 may cover the first connection electrode 26, but may not be disposed on another end portion of the light emitting element 30 so that the light emitting element 30 may be in contact with the second connection electrode 27. The third insulating layer 53 may be in partial contact with the first connection electrode 26 and the second insulating layer 52 on an upper surface of the second insulating layer 52. A side surface of the third insulating layer 53 in a direction in which the second electrode 22 is disposed may be aligned with a side surface of the second insulating layer 52. For example, the third insulating layer 53 may also be disposed on the non-emission area, for example, on the first insulating layer 51 disposed on the first planarization layer 19. However, embodiments are not limited thereto.

The second connection electrode 27 may be disposed on the second electrode 22, the second insulating layer 52, and the third insulating layer 53. The second connection electrode 27 may be in contact with another end portion of the light emitting element 30 and the exposed upper surface of the second electrode 22. The another end portion of the light emitting element 30 may be connected (e.g., electrically connected) to the second electrode 22 through the second connection electrode 27.

For example, the first connection electrode 26 may be disposed between the first electrode 21 and the third insulating layer 53, and the second connection electrode 27 may be disposed on the third insulating layer 53. The second connection electrode 27 may be in partial contact with the second insulating layer 52, the third insulating layer 53, the second electrode 22, and the light emitting element 30. An end portion of the second connection electrode 27 may be disposed on the third insulating layer 53. The first connection electrode 26 and the second connection electrode 27 may not be in contact with each other by the second insulating layer 52 and the third insulating layer 53. However, embodiments are not limited thereto, and in some cases, the third insulating layer 53 may be omitted.

The connection electrodes 26 and 27 may include a conductive material. For example, the connection electrodes 26 and 27 may include ITO, IZO, ITZO, aluminum (Al), or the like. As an example, the connection electrodes 26 and 27 may include a transparent conductive material, and the light emitted from the light emitting elements 30 may be transmitted through the connection electrodes 26 and 27 and may transmit toward the electrodes 21 and 22. Each of the electrodes 21 and 22 may include a material having high reflectivity, and the electrodes 21 and 22 disposed on the inclined side surfaces of the first banks 40 may reflect the light incident thereon in an upward direction of the first substrate 11. However, embodiments are not limited thereto.

A fourth insulating layer 54 may be disposed (e.g., entirely disposed) on the first substrate 11. The fourth insulating layer 54 may protect members disposed on the first substrate 11 from an external environment.

Each of the first insulating layer 51, the second insulating layer 52, the third insulating layer 53, and the fourth insulating layer 54 described above may include an inorganic insulating material or an organic insulating material. In an embodiment, the first insulating layer 51, the second insulating layer 52, the third insulating layer 53, and the fourth insulating layer 54 may include an inorganic insulating material such as silicon oxide (SiOₓ), silicon nitride (SiNₓ), silicon joxynitride (SiOₓN_{y}), aluminum oxide (AlOₓ), or aluminum nitride (AlNₓ). In another example, the first insulating layer 51, the second insulating layer 52, the third insulating layer 53, and the fourth insulating layer 54 may include an organic insulating material such as an acrylic resin, an epoxy resin, a phenolic resin, a polyamide resin, a polyimide resin, an unsaturated polyester resin, a polyphenylene resin, a polyphenylene sulfide resin, a benzocyclobutene, a cardo resin, a siloxane resin, a silsesquioxane resin, polymethyl methacrylate, polycarbonate, or polymethyl methacrylate-polycarbonate synthetic resin. However, embodiments are not limited thereto.

The inkjet printing apparatus 1000 may jet the light emitting elements 30 onto the electrodes 21 and 22 of the display device 10 through the inkjet device 300. For example, the electric field generating device 700 may be electrically connected to the respective electrodes 21 and 22 to generate the electric field EL on the respective electrodes 21 and 22, and the light emitting elements 30 may be aligned on the electrodes 21 and 22 by the electric field EL. According to an embodiment, the display device 10 may be manufactured by printing the light emitting element 30 disposed on the electrodes 21 and 22 by using the inkjet printing apparatus 1000.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation.

1. An inkjet printing apparatus comprising:
a stage that moves in a first direction;
an inkjet device that sprays ink onto the stage;
a plurality of electric field generating devices that geneerate an electric field on the stage, the plurality of electric field generating devices that are spaced apart from the stage and are movable in the first direction independently from the stage;
a light irradiation device that irradiates the stage with light and
a drying device that dries the ink sprayed onto the stage,
wherein the inkjet device, the light irradiation device, and the drying device are disposed along the first direction.

2. The inkjet printing apparatus of claim 1, wherein the plurality of electric field generating devices are configured to generate the electric field on the stage with moving along the stage.

3. The inkjet printing apparatus of claim 2, wherein
the plurality of electric field generating devices includes:
a first electric field generating device disposed on a side of the stage, and
a second electric field generating device disposed on another side of the stage and
the first electric field generating device and the second electric field generating device are spaced apart from each other and are movable the first direction independently from each other.

4. The inkjet printing apparatus of claim 3, wherein at least one of the first electric field generating device and the second electric field generating device is configured to move in a direction opposite to a moving direction of the stage in case that the stage moves to the drying device.

5. The inkjet printing apparatus of claim 1, wherein the inkjet device is configured to spray the ink onto the stage on which the electric field is generated by the plurality of electric field generating devices.

6. The inkjet printing apparatus of claim 5, wherein
the ink includes a solvent and a plurality of bipolar elements dispersed in the solvent, and
end portions of the bipolar elements are oriented to have initial orientation directions by the electric field.

7. The inkjet printing apparatus of claim 6, wherein the light irradiation device is configured to irradiate the ink disposed in the electric field with the light.

8. The inkjet printing apparatus of claim 7, wherein in case that the ink is irradiated with the light, the initial orientation directions of end portions of some of the bipolar elements are changed by the electric field and the light.

9. The inkjet printing apparatus of claim 1, further comprising:
a plurality of rails including a first rail and a second rail extending in the first direction, and
a plurality of frames including a first frame and a second frame disposed above the first rail and the second rail,
wherein
the stage is disposed on the first rail,
the plurality of electric field generating devices are disposed on the second rail, and
the stage and the plurality of electric field generating devices are configured to pass below the plurality of frames with moving in the first direction.

10. The inkjet printing apparatus of claim 9, wherein
the inkjet device is disposed on the first frame, and
the light irradiation device includes:
a first light irradiation device disposed on the first frame, and
a second light irradiation device disposed on the second frame spaced apart from the first frame in the first direction.

11. The inkjet printing apparatus of claim 10, wherein
the ink is sprayed in case that the stage moves to the first light irradiation device, and
the first light irradiation device is configured to irradiate the stage with the light in case that the ink is sprayed onto the stage.

12. The inkjet printing apparatus of claim 11, wherein the second light irradiation device is configured to irradiate the stage with the light after the ink is sprayed onto the stage.

13. The inkjet printing apparatus of claim 9, wherein
the drying device includes a first drying device to which the plurality of electric field generating devices and the stage move, and
the stage is configured to move to the first drying device in a state in which the electric field is generated.

14. The inkjet printing apparatus of claim 13, wherein
the drying device further includes a second drying device including an electric field generating unit different from the plurality of electric field generating devices, and
the electric field generating unit is configured to generate an electric field on the stage in case that the stage moves to the second drying device.

15. The inkjet printing apparatus of claim 14, further comprising a sub-stage which is disposed below the second drying device and on which the electric field generating unit is disposed,
wherein the stage and the plurality of electric field generating devices are configured not to move to the second drying device.

16. A printing method of a bipolar element, comprising:
providing a target substrate
generating an electric field on the target substrate; and
spraying ink onto the target substrate, the ink including a solvent and bipolar elements dispersed in the solvent;
arranging the bipolar elements on the target substrate by irradiating the ink disposed in the electric field with light; and
seating the bipolar elements on the target substrate by removing the solvent of the ink.

17. The printing method of the bipolar element of claim 16, wherein in the spraying of the ink onto the target substrate, end portions of the bipolar elements are oriented to have initial orientation direction by the electric field.

18. The printing method of the bipolar element of claim 17, wherein in the arranging of the bipolar elements, the initial orientation directions of end portions of some of the bipolar elements are changed by the electric field and the light.

19. The printing method of the bipolar element of claim 18, wherein the target substrate is irradiated with the light in case that the ink is sprayed.

20. The printing method of the bipolar element of claim 17, wherein the seating of the bipolar elements includes removing the solvent in a state in which the electric field is generated on the target substrate.

21. The printing method of the bipolar element of claim 20, wherein
the target substrate includes a first electrode and a second electrode spaced apart from each other, and
the end portions of the bipolar elements are disposed on the first electrode and another end portion disposed on the second electrode.
